(19) United States
(12) Patent Application Publication
(10) Pub. No.: US 2015/0053908 A1
(43) Pub. Date: Feb. 26, 2015

(54) MEMRISTIVE DEVICE AND METHOD OF MANUFACTURE

(71) Applicant: PRIVATRAN, INC., Austin, TX (US)

(72) Inventor: Burt Fowler, Buda, TX (US)

(73) Assignee: Privatran, Austin, TX (US)

(21) Appl. No.: 14/384,035

(22) PCT Filed: Mar. 11, 2013
(86) PCT No.: PCT/US2013/030124

§ 371 Date: Sep. 9, 2014

Related U.S. Application Data
(60) Provisional application No. 61/609,058, filed on Mar. 9, 2012.

(51) Int. Cl. H01L 45/00; H01L 27/24

(52) U.S. Cl. CPC H01L 45/1608; H01L 45/1641; H01L 45/1675; H01L 45/1253; H01L 27/2463
USPC 257/4; 438/382

(57) ABSTRACT

A device with programmable resistance comprising memristive material between conductive electrodes on a substrate or in a film stack on a substrate is provided. During fabrication of a memristive device, a memristive layer may be hydrated after deposition of the memristive layer. The hydration of the memristive layer may be performed utilizing thermal annealing in a reducing ambient, implant or plasma treatment in a reducing ambient, or a deionized water rinse. Additionally, plasma-assisted etching of an electrode may be performed with hydration or in place of hydration to electroform devices in a batch, in situ process. The memristive device may be electroformed at low voltage and passivated to allow for device operation in air. Further, the memristive device is suitable for high throughput manufacturing.

### RELATED APPLICATIONS

This application claims the benefit of U.S. Provisional Patent Application No. 61/609,058 to Fowler, filed on Mar. 9, 2012, which is incorporated herein by reference.

### FIELD OF THE INVENTION

This invention relates to a memristive device and methods of manufacture. More particularly, to memristive devices improved by hydration and/or plasma treatments.

### BACKGROUND OF INVENTION

In 1971, Dr. L. O. Chua in UC-Berkeley introduced a new two-terminal circuit element, called the memristor, as the fourth basic circuit element. At that time, a physical memristor device without internal power supply had not yet been discovered. After nearly four decades, the existence of memristors was demonstrated, which potentially enable a new generation of nonvolatile memory and data storage solutions. Resistance-change materials including metal oxides (NiO, TiO₂, etc.), chalcogenides and organic materials have been studied as potential candidates for future nonvolatile memory. These resistance-change materials may exhibit bipolar properties when switching between high resistance state (HRS) and low resistance state (LRS), while SiOₓ exhibits unipolar state switching properties. This makes SiOₓ suitable for future RRAM applications in terms of scalability and integration.

A memristive or memresistive device is an electronic device that can change conductivity. For example, a memristive device may provide a high conductivity state when a first voltage is applied to the memristive device, and the memristive device may provide a low conductivity state when a second voltage is applied to the memristive device. A memristive device may provide memristive material that provides two or more conductivity states after electroformation or conditioning. Nonlimiting examples of memristive materials include SiOₓ, metal oxides, or the like. A memristive device may be utilized in a variety of electronic applications such as, but not limited to, nonvolatile storage, memory arrays, 3-D memory, switching, reconfigurable and rapidly-tunable bandpass and notch filters, reversible field programmable fuse arrays, sample and hold elements, programmable resistance elements within a variable-gain amplifier, and analog to digital converters, and the like. Additionally, a memristive device may be integrated with other electronic components such as, but not limited to, diodes, transistors, or other electronic components. While memristors, memresistors, memory resistors, or resistive memory devices may be referred to herein, it is noted that these terms are utilized interchangeably and are not limited to use in memory devices.

Some memristive devices have active memristive material at an edge, a sidewall or a surface of the memristive material between two electrodes. As a result, such edge, sidewall, or surface memristive devices are limited to manufacturing techniques and device structures that can provide such edges, sidewalls or surfaces of memristive material between two electrodes. For example, such edge, sidewall, or surface memristive devices may require higher electroformation voltages, larger device sizes, non-standard structures, higher power requirement or complexity. Dielectric-based memristive device architectures and manufacturing methods discussed herein form memristive material “in the bulk” of dielectric material between the two electrodes without requiring any edge, sidewall or surface between the two electrodes in order to support the device. Device architectures and manufacturing methods are described herein that enable passivated, electrically-isolated memristive devices, or an array of memristive devices, to be integrated with conventional technology platforms to achieve a high-density nonvolatile memristive device array.

### SUMMARY OF THE INVENTION

In one embodiment, a method for fabricating a memristive device comprises forming a first electrode and depositing a memristive layer. The memristive layer is hydrated utilizing a reducing ambient, wherein the reducing ambient is H₂, D₂, H₂O, D₂O, NH₃, H or D containing gas mixtures, or a combination thereof. Additionally, second electrode may be deposited or formed. The hydration treatment may be a thermal anneal of the memristive layer in the reducing ambient; a plasma treatment of said memristive layer in the reducing ambient; or a deionized water rinse and drying in any inert ambient.

In another embodiment, a method for fabricating a memristive device comprises forming a first electrode and depositing a memristive layer. The memristive layer may be subjected to a thermal anneal in a reducing ambient, wherein the reducing ambient is H₂, D₂, H₂O, D₂O, NH₃, H or D containing gas mixtures, or a combination thereof. Additionally, second electrode may be deposited or formed.

In yet another embodiment, a method for fabricating a memristive device comprises forming a first electrode and depositing a memristive layer. After a second electrode is formed, the second electrode may be etched utilizing plasma-assisted etching, thereby causing the memristive layer to be electroformed. The hydration treatment, thermal anneal, or plasma-assisted etching result in reduced electroformation voltages when activating the memristive layer. In some embodiments, a combination of hydration, thermal anneal, or plasma-assisted etching may be utilized during fabrication of a memristive device.

In yet another embodiment, a memristive device may include a first electrode, a second electrode, a memristive layer disposed between the first and second electrodes, and a passivation layer covering exposed portions of the memristive layer. In some embodiments, the memristive layer is hydrated utilizing a reducing ambient after deposition, wherein the reducing ambient is H₂, D₂, H₂O, D₂O, NH₃, H or D containing gas mixtures, or a combination thereof. In some embodiments, the memristive layer may be subjected to a thermal anneal in a reducing ambient, wherein the reducing ambient is H₂, D₂, H₂O, D₂O, NH₃, H or D containing gas mixtures, or a combination thereof. In some embodiments, the second electrode may be etched utilizing plasma-assisted etching, thereby causing the memristive layer to be electroformed.

The foregoing has outlined rather broadly various features of the present disclosure in order that the detailed description that follows may be better understood. Additional features and advantages of the disclosure will be described hereinafter.

### BRIEF DESCRIPTION OF THE DRAWINGS

For a more complete understanding of the present disclosure, and the advantages thereof, reference is now made to the following descriptions to be taken in conjunction with the accompanying drawings describing specific embodiments of the disclosure, wherein:

FIGS. 1A-1K show a process flow diagram and corresponding device structure;

FIGS. 2A-2D show (a) current-voltage response of ON and OFF states with resistance plotted in inset, simplified energy band diagrams in (b) ON (defect-assisted tunneling) and (c) OFF (Poole-Frenkel conduction) states, and (d) reversible switching mechanism forming electrically-active Si—H—Si in the ON state and inactive Si—HH—Si in the OFF state;

FIGS. 3A-3D show electroforming voltage sweep for (a) control device without PDA, (b) device with PDA in N₂ ambient, (c) device with PDA in H₂/N₂ ambient, (d) device with PDA in D₂/N₂ ambient;

FIG. 4 shows a top down view of a memristive device unit cell;

FIGS. 5A-5B show cross-section drawings of a memristive device unit cell;

FIG. 6 shows a device circuit schematic of a memristive device unit cell;

FIGS. 7A-7G show a process flow for forming memristive device within a contact hole or via opening;

FIGS. 8A-8B show cross-sections of memristive devices formed within a contact or via using (a) large feature size technology and (b) small feature size technology with feature size of 45 nm or less;

FIGS. 9A-9B show (a) SEM image of M2 TiW/Au line over planarized M1 TiW line, and (b) SEM cross-section image of a planarized TiW electrode with 50 nm SiO₂ layer and 100 nm TiW top electrode;

FIG. 10 shows conditioning curves for devices with sidewall (curves 1-4, 13) showing successful electroformation, and without sidewall (Control) showing no electroformation;

FIGS. 11A-11C show single-mask test structures with (a) and without (b) sidewall, and test set-up (c);

FIGS. 12A-12B show schematic representations of plasma reactor with (a) lower electrode connected to wafer chuck; and (b) modified configuration for improved control of forming voltage using edge connection to device lower electrode and controllable bias V_{CNTR} (Dashed line shows lower electrode connection to chuck when insulating substrate is used and V_{CNTR} is not used);

FIGS. 13A-13B show: (a) current versus voltage for ON and OFF states; and (b) current versus cycle number for a Pd/SiO₂/Si device with SU8 passivation (inset of a) operating in air at room temperature;

FIGS. 14A-14B show schematic representations of reactor with vacuum electron source using (a) edge ring to contact lower electrode in vertical device architecture; and (b) modified configuration using two electrical contacts to a planar device architecture;

FIGS. 15A-15B show schematic representations of reactor with: (a) global thermal energy source using a bank of tungsten halogen lamps to aid electroformation of planar device; and (b) a configuration using a scanning laser as the thermal energy source to directly write devices;

FIGS. 16A-16B show selective-area device formation using thermal anneal after planar electrode patterning: (a) reducing anneal process and dopant drive-in; and (b) showing the subsequent electroformation using direct biasing, vacuum electrons, or thermal energy; and

FIG. 17A-17B show schematic representations of reactor with: (a) vacuum electron source using (a) scanning tunneling microscope (STM); and (b) a focused, scanning electron beam for direct writing of devices.

### DETAILED DESCRIPTION

Refer now to the drawings wherein depicted elements are not necessarily shown to scale and wherein like or similar elements are designated by the same reference numeral through the several views.

Referring to the drawings in general, it will be understood that the illustrations are for the purpose of describing particular implementations of the disclosure and are not intended to be limiting thereto. While most of the terms used herein will be recognizable to those of ordinary skill in the art, it should be understood that when not explicitly defined, terms should be interpreted as adopting a meaning presently accepted by those of ordinary skill in the art.

It is to be understood that both the foregoing general description and the following detailed description are exemplary and explanatory only, and are not restrictive of the invention, as claimed. In this application, the use of the singular includes the plural, the word “a” or “an” means “at least one”, and the use of “or” means “and/or”, unless specifically stated otherwise. Furthermore, the use of the term “including”, as well as other forms, such as “includes” and “included”, is not limiting. Also, terms such as “element” or “component” encompass both elements or components comprising one unit and elements or components that comprise more than one unit unless specifically stated otherwise.

A memristive or memresistive device is an electronic device that can change conductivity. For example, a memristive device may provide multiple conductivity states in response to different voltages or currents applied to the device. Nonlimiting examples of memristive materials may include SiOₓ, metal oxides, or the like. In some embodiments, the memristive material may be SiOₓ, where 1≦x≦2. Memristive devices may be utilized for several electronic applications such as, but not limited to, nonvolatile storage, memory arrays, 3-D memory, switching, reconfigurable and rapidly-tunable bandpass and notch filters, reversible field programmable fuse arrays, sample and hold elements, programmable resistance elements within a variable-gain amplifier, and analog to digital converters, and the like. To operate as a memristive device, the device may be conditioned, or electroformed, by applying bias voltages of at least two different magnitudes. This may result in formation of active memristive materials at an edge, sidewall or surface of the memristive material between two electrodes that provides multiple conductivity states. The high voltages (e.g. 20V or greater) required to condition these devices increases device size, power requirements and complexity, making it more difficult to integrate the device with commercial manufacturing process flows.

Memristive devices and methods of manufacture discussed herein provide device architectures and manufacturing methods to lower the electroformation voltage, enable integration with conventional microelectronics technology platforms, and/or improve device repeatability, reliability and operating performance. In one embodiment, a hydration treatment may be performed on said memristive layer after deposition of said memristive layer. The hydration treatment serves to preserve high point defect concentration by hydrating the memristive layer. Hydration treatment may comprise thermal annealing in a reducing ambient, implant or plasma treatment in reducing ambient, deionized (DI) water rinse, and/or a combination thereof. For example, when the memristive layer is silicon oxide, a hydration treatment allows point defects to bond with a reducing ambient, thereby aiding electroformation as discussed further below. An optional, hardmasking step may be performed prior to hydration to allow for selective hydration treatment to specific areas of the memristive layer.

A post-deposition anneal (PDA) may enable device formation in the bulk memristive material without the need for additional process steps to form a sidewall, or any type of surface, between the two electrodes during manufacturing. In some embodiments, the PDA is a thermal anneal in reducing ambient at a predetermined temperature for a predetermined time. In some embodiments, the reducing ambient may be H₂, D₂, H₂O, D₂O, NH₃, other gas mixtures containing H or D, a combination thereof or the like. In some embodiments, the temperature of the thermal anneal is in a range equal to or between 100° C. to 700° C. In some embodiments, the thermal anneal time is equal to or between 30 seconds to 30 minutes. For example, a silicon oxide layer may be subjected to thermal anneal in a mixture of deuterium (D₂) and nitrogen (N₂) at temperatures ranging from 100 C to 700 C for 30 seconds to 30 minutes. Thermal anneal has been found to lower the electroformation voltage from near 20V in untreated devices to near 5V when the anneal is applied after the memristive material is deposited.

In some embodiments, the hydration treatment may be a plasma treatment in a reducing ambient, such as a plasma treatment in a plasma reactor. In some embodiments, the hydration treatment may be a DI water rinse, such as DI water rinse and room temperature drying in a reducing ambient.

In some embodiments, lowering electroformation voltage may be aided by plasma-assisted dry etch of an electrode so that the device can be electroformed in situ during the dry etch process to form the memristive device. In some embodiments, the plasma-assisted etching may be the only treatment to improve electroformation, and in other embodiments the plasma-assisted etching may be combined with other treatments that lower electroformation voltages, such as hydration treatment. In other embodiments, methods other than plasma-based treatments such as using a vacuum electron source or directed thermal energy may be utilized for batch electroformation, which also provide high throughput, batch processing. When integrated with a suitable passivation layer, the bulk memristive device can operate in air at room temperature as opposed to devices formed at a sidewall or surface that only operate in vacuum or high-purity ambients that are free of oxygen and water.

Dielectric-based memristive device architectures and manufacturing methods are discussed herein. A memristive device can be formed using a first electrode, a deposited or thermally-grown dielectric memristive material, post-deposition anneal treatment of the dielectric layer, a second electrode that is deposited and patterned, and a passivation layer to enable insulated electrical connection and device operation in air. The memristive devices discussed herein form active memristive material “in the bulk” of dielectric material between the two electrodes without requiring any edge, sidewall or surface between the two electrodes to be fabricated in order to support the device. As such, the memristive devices and methods of manufacture discussed herein are not constrained by the need to provide an edge, sidewall or surface during fabrication. Further, memristive devices discussed herein may also provide lower electroformation voltages, smaller device sizes, lower power requirements, and/or less complexity. While embodiments discussed herein may refer to examples discussing memristive devices formed “in the bulk,” it is noted that the device architectures and manufacturing methods discussed herein may also be applied to edge, sidewall or surface memristive devices with similar benefits.

Device architectures, process treatments and integration methods are described herein. In some embodiments, the memristive material is treated after deposition using thermal anneal in reducing ambient. In some embodiments, additional treatment can be done during or after top electrode patterning to provide: lower and more consistent conditioning voltage (or electroformation voltage) of devices in bulk- and sidewall-supported devices; formation of devices without need for a sidewall, edge or surface; device electroformation without the need for direct electrical contact; and electrical and/or environmental passivation using conventional materials and manufacturing methods.

Provided herein is a device with programmable resistance comprising memristive material between two conductive traces on a substrate or in a film stack on a substrate. In some embodiments, the substrate is silicon, Si, silicon carbide, SiC, gallium arsenide, GaAs, or indium phosphide, InP. In some embodiments, the conductive material for electrodes may be n-type doped polysilicon, p-type doped polysilicon, tungsten, titanium-tungsten alloy, tungsten silicide, titanium, titanium-tungsten alloy, titanium-nitride alloy, tantalum, tantalum-nitride alloy, tantalum silicide, aluminum, palladium, copper, gold, platinum silicide, titanium silicide, cobalt silicide, nickel silicide, tungsten silicide, or a combination thereof. In one embodiment, an upper conductive trace is doped poly-silicon, a lower conductive trace is doped single-crystal silicon, and the memristive material is silicon dioxide. Other embodiments may use metal electrodes in a film stack, or two adjacent metal electrodes deposited on a substrate. While embodiments discussed herein refer to SiOₓ as the memristive material, any suitable memristive material may be utilized.

One embodiment may provide a conductive or semiconducting substrate as a lower electrode; a thin silicon dioxide layer as the active memristive material; thermal anneal in a reducing ambient; deposition, pattern and etch of a conductive upper electrode; batch electroformation by treatment with a plasma or vacuum electron source; and deposition, pattern and etch of a dielectric passivation layer. The passivation layer may be formed from an insulating material. In some embodiments, the insulating material is Si₃N₄, SiOₓN_{y}, SiNₓC_{y}, SiC, borosilicate glass, BSG, phosphosilicate glass, PSG, boro-phosphosilicate glass, BPSG, polyimide, epoxy-based photoresist and epoxy, or a combination thereof. Controlling the thermal anneal and plasma (or vacuum electron) process settings leads to a device capable of operating in room air without the need for an extensive, high-voltage electroformation process.

Another embodiment uses a patterned film stack that includes first insulator; first conductor; memristive dielectric; second conductor; and second insulator deposited on a substrate with each layer being patterned. The first conductor is patterned to form a lower electrode, followed by memristive material deposition and thermal anneal. Openings in the memristive layer are made in some regions for contacts to the lower electrode. The second conductor layer is deposited, patterned and etched to form an upper electrode. After the upper electrode is formed, global electrical contact is made to the lower electrode and a plasma- or vacuum electron-based treatment may be used to apply a controlled bias across the electrodes so that device electroformation occurs in situ as a batch process. The second insulator layer is used for device passivation to protect against oxygen and water contamination.

In some embodiments, multiple memristive devices may be interconnected to form memory arrays and to provide memory element isolation from neighboring elements.

The memristive device discussed herein can be used in applications where a nonvolatile memory is to be integrated with other microelectronic circuitry. Novel architectures for silicon oxide memristive devices is discussed herein. The manufacturing methods and process treatments enable device operation in air by use of conventional passivation materials for improved long-term reliability. Device operating performance, reproducibility and yield should improve dramatically by implementation in a manufacturing environment. These improvements will significantly increase manufacturing throughput and will enable device integration with large-scale, low-cost commercial manufacturing technologies.

The memristive device and arrays can have numerous applications. In some embodiments, memristive device arrays can be used as addressable two-terminal nonvolatile memory arrays. Compared to conventional flash memory using three-terminal transistors as basic building elements, the memristive device arrays adopt a two-terminal configuration and therefore simplify the architecture. This in turn can facilitate the possibility of 3-D memory. Other applications include, but are not limited to, use as reconfigurable and rapidly-tunable bandpass and notch filters, reversible field programmable fuse arrays, sample and hold elements, programmable resistance elements within a variable-gain amplifier, analog to digital converters, and the like.

Furthermore, due to a strong resilience to ionizing radiation exposure, the memristive devices and arrays can also be used within the context of nonconventional electronic devices that operate in harsh environments, such as outer space and other high-radiation environments. Moreover, the components used in the memristive devices and arrays are prevalent and standard making them fully compatible with current semiconductor manufacturing methods and fabrication techniques.

In some implementations, the fabrication steps are as follows:

1) Depositing a conductive lower electrode. In some embodiments, the lower electrode may be a conducting or semiconducting substrate. In some embodiments, this step may also include patterning the lower electrode.

2) Forming a memristive layer over the lower electrode, wherein the first layer is memristive material. Nonlimiting examples of memristive materials include SiOₓ, metal oxides, or the like.

3) In some embodiments, a hydration treatment may be performed after deposition of the memristive layer. The hydration treatment may comprise one or more of the following:
a) Thermal annealing of the memristive layer in reducing ambient. In some embodiments, the reducing ambient may be H₂, D₂, H₂O, D₂O, NH₃, other gas mixtures containing H or D, a combination thereof or the like.
b) Implant or plasma treatment of the memristive layer in a reducing ambient. In some embodiments, the reducing ambient may be H₂, D₂, H₂O, D₂O, NH₃, other gas mixtures containing H or D, a combination thereof or the like.
c) DI water rinsing of the memristive layer. In some embodiments, the memristive layer may be hydrated by exposure to a DI H₂O rinse, and may be followed by drying in N₂ or any other inert gas

4) Depositing a second layer of conductive material over the first layer. In some embodiments, this step may also include patterning the second layer to form an upper electrode.

5) Electroformation treating the device with a vacuum electron source, plasma and/or thermal treatment. In some embodiments, electroformation treatment may be combined with plasma-assisted etching to activate the memristive layer in situ during etching of an upper electrode.

6) Depositing a third layer of insulating material. The insulating material may have low permeability to oxygen and water to enable operation in air.

7) Forming openings in the third layer to allow electrical contact to upper electrode.

In some embodiments, the fabrication process is modified to deposit the insulating layer onto a substrate first or simply uses an insulating substrate, followed by deposition and patterning of a conductive material to form the lower electrode. In such embodiments, the openings formed in Step 7 above may also allow electrical contact to lower electrode. Steps 3 and 5 can be tuned to provide operation as a bulk device, low electroformation voltage, and batch electroformation.

Another embodiment forms the memristive device inside a contact or via within the conventional process capabilities of current microelectronics manufacturing technology. In some embodiments, this may be done by incorporating the silicon oxide memristive layer into the layer stack typically used to fabricate the contact or via.

If Cu, Au or other metal materials that diffuse readily in silicon oxide are used as electrodes, a barrier metal between the memristive material and the electrode may be used to protect from electromigration and metal ion diffusion into active device regions.

Reducing anneal refers to the application of thermal energy in an ambient that promotes an oxygen reduction reaction. For example, a reducing anneal used in the microelectronics industry is forming gas anneal in ambient comprised of 1-20% H₂ in a balance of N₂ with anneal temperature (T) depending on the point within the process flow where the reducing anneal is applied. Prior to metallization, T is typically limited to less than 1000° C. for very short times to preserve dopant profiles within the substrate. After metallization (meaning the inclusion of W, Al, TiN, Cu, other metals, or metal ion diffusion barriers into the device), T is typically less than 450 C for no more than 30 minutes in order to limit grain boundary growth in metal interconnect lines. The reducing anneal is used to terminate un-bonded atoms at Si-to-SiO₂ interfaces, for purposes such as to improve transistor performance, which is generally referred to as “defect passivation.” Forming gas anneal is also used throughout fabrication of the multiple (in some cases more than 10) metal interconnect layers to terminate trapped charges at metal/dielectric interfaces and to passivate, i.e. to render electrically inactive, defects within the dielectric layers. While an exemplary reducing anneal is discussed above, any suitable reducing anneal process may be utilized.

A reducing ambient is considered to be an ambient that contains molecules that passivate point defects within the memristive material. For example, ambient containing H₂, D₂, H₂O or D₂O are considered to be a reducing ambient since each of these are expected to passivate point defects within bulk SiO₂ materials and lead to low-energy oxygen reduction pathways and lower electroformation voltage. Other gases or gas mixtures that contain H or D, for example ammonia (NH₃), can also be used as a reducing ambient as long as the decomposition products of the molecule lead to effective passivation of point defects in memristive material, such as SiO₂ bulk material. In some embodiments, a reducing ambient may be deuterium, D₂, diluted from 1% to 20% in inert gas. In some embodiments, a reducing ambient may be hydrogen, H₂, diluted from 1% to 20% in inert gas. In some embodiments, a reducing ambient may be water vapor, H₂O, diluted from 1% to 20% in inert gas. In some embodiments, a reducing ambient may be deuterated water vapor, DₓH₂₋ₓO, where 0≦x≦2, diluted from 1% to 20% in inert gas. In some embodiments, a reducing anneal may be performed in 4% D₂ in N₂ at 400 C for 5 minutes.

In addition to SiO₂ and SiOₓ, other memristive materials including HfO₂, Al₂O₃, SiOₓN_{y} and SiOₓC_{y}H_{z} may benefit from the hydration and batch electroforming methods described herein.

An important feature of the manufacturing method is that it provides the passivation of “point” defects within the bulk of the as-deposited SiO₂ layer used to form the memristive device. Such point defects may be classified as oxygen vacancy defects, and the passivation process proceeds as

≡Si—Si≡+H₂→≡Si—HH—Si≡ (1)

where ≡Si—Si≡ represents the oxygen vacancy defect. When H₂ is near the ≡Si—Si≡ defect in an amorphous SiO₂ network, only 1.7 eV is required to break the hydrogen molecule and passivate the two Si atoms.

Use of H₂O in the anneal ambient instead of H₂ can also promote formation of H-complexed oxygen vacancy defects. The primary decomposition pathway of water in SiO₂ is formation of two hydroxyl groups

≡Si—O—Si≡+H₂O→≡Si—OHHO—Si≡ (2)

and the reaction of water with an oxygen vacancy defect is

≡Si—Si≡+H₂O→≡Si—HHO—Si≡ (3)

where a hydroxyl group (OH) and Si—H are formed. The reaction of two interstitial water molecules in a larger-than-normal pore within the SiO₂ network forms a localized H₃O⁺ defect and OH⁻, where the OH⁻ can become interstitial and diffuse away with only 0.3 eV of energy, but the H₃O⁺ defect can attach to a network O atom through a O—H—O linkage and remain localized within the pore.

Anneal in both H₂ and H₂O can therefore passivate point defects within the bulk SiO₂ layer by forming H-complexed oxygen vacancies. Oxide materials deposited under conditions that lead to a high point defect concentration and high porosity, such as, by non-limiting example, plasma-enhanced chemical vapor deposition, electron beam evaporation or physical vapor deposition, can then be annealed in reducing ambient to preserve the as-deposited point defect concentration. This defect concentration will then be available when the device is subsequently electroformed.

Specifically, when placed under electrical stress, the ≡Si—HH—Si≡ defect can lead directly to localized oxygen reduction through the following low-energy pathways:

h⁺+≡Si—HH—Si≡→≡Si—H—Si≡+H⁺ (4)

where h⁺ is a hole injected into the SiO₂ layer from the anode, which is known to promote emission of a proton (H⁺); leading to formation of the hydrogen bridge defect, which can further capture a hole such that

h⁺+≡Si—H—Si≡+≡Si—O—Si≡→≡Si—H Si—O⁺═Si₂ (5)

where one of the Si atoms in the hydrogen bridge back-bonds to a network O atom. The Si—H defect is relatively stable but the —O⁺═ defect is a positively-charged, 3-fold coordinated oxygen atom that can diffuse away as O²⁻, leaving behind a Si dangling bond defect, ≡Si— [4], and creating another oxygen vacancy defect

≡Si—H≡Si—O⁺═Si₂→≡Si—H+≡Si—+≡Si—Si≡+O^{2˜} (6)

In this way, hole injection into the SiO₂ layer during electroformation can lead directly to oxygen reduction and provide the precursors for Si nucleation through low-energy pathways.

When D₂ is used instead of H₂, the chemical reactions are expected to be essentially the same, but in the case of passivating dangling Si bonds under high electrical stress conditions, it is understood that Si-D is a much more stable defect than Si—H. Because the electroformation process is a high electrical stress condition, the effect of D₂ anneal may be to promote the oxygen reduction reaction

≡Si-D≡Si—O⁺═Si₂→≡Si-D+≡Si—+≡Si—Si≡+O²⁻ (7)

by stabilizing the Si-D defect and reducing the probability for D desorption by high-energy (>˜3 eV) electrons, thereby increasing the probability that the —O⁺═ defect will diffuse away or drift in the applied electric field, as compared to the case of a H-passivated Si—H defect.

These low-energy pathways may explain the experimental results showing that both H₂ and D₂ anneal significantly reduce the voltage required for electroformation in SiO₂ materials, and why the D₂ anneal provides an even lower electroformation voltage than H₂ anneal as discussed further below.

As described by the above reactions, during the electroformation process, the high electric field and hot carrier injection create charged species such as H⁺, H₃O⁺, OH⁻, O²⁻, ≡Si—Si≡ (positive or neutral charged), ≡Si—HH—Si≡ (positive or neutral charged) and ≡Si—H—Si≡ (positive, neutral or negative charged). As these defects drift or diffuse through the SiO₂ layer, there are many potential reactions that can occur; however, only the reactions having stable products can result in reversible switching. Due to its reaction products, of particular interest is the reaction between H₃O⁺ and the negative charged ≡Si—H⁻—Si≡ defect, which forms H₂O and ≡Si—HH—Si≡ by transfer of a single proton. By analogy with the reaction ≡Si—H⁻—Si≡+H⁺→≡Si—HH—Si≡, which is known to occur based on first principles density functional theory calculations, the reaction ≡Si—H⁻—Si≡+H₃O⁺→≡Si—HH—Si≡+H₂O, would be expected to release ˜3 eV of energy, which is about twice the activation energy barrier of 1.5 eV for the interstitial H₂O molecule to react with the SiO₂ network to form the stable defect ≡Si—OHHO—Si≡. The reaction

≡Si—H⁻—Si≡+Si₂═O—H₃O⁺←→≡Si—HH—Si≡+≡Si—OHHO—Si≡ (8)

can therefore support reversible switching since the ≡Si—H—Si≡ defect is a conductive defect in SiO₂ (based on its thermodynamic energy level being near the Fermi level of most common electrode materials) whereas the ≡Si—HH—Si≡ defect is a non-conductive defect with thermodynamic energy level far from the Fermi level that traps electrons in a shallow, neutral-charged energy level near the SiO₂ valance band-edge. As such, the left-hand side of reaction (8) forms a conductive defect state and the right-hand side forms a non-conductive defect state. As shown above in reaction (4), hole injection into the ≡Si—HH—Si≡ defect can result in H⁺ emission. As understood by density functional theory calculations, an interstitial H₂O molecule can uptake a H atom bonded at an SiO₂/Si interface to form H₃O⁺ with ˜0 eV being required when a hole is available. By analogy with this reaction, the water molecule in the ≡Si—OHHO—Si≡ defect would be expected to uptake the H⁺ emitted by the ≡Si—HH—Si≡ defect to drive the reverse reaction in (8). Once the electroformation process proceeds to the point where a conductive pathway of these defect complexes is created, electroformation is complete and the conditions for reversible switching are established. The electroformation process is a one-time event, after which the device can be operated as a reversible switch or memory element. As discussed further below, the energy required to initiate H⁺ emission from the ≡Si—HH—Si≡ defect, 2.6 eV, can be assigned to the turn-ON transition in the current-voltage response, which occurs near 2.5 V. Although defect complexes other than the specific complex described by reaction (8) could potentially support reversible switching by the transfer of a single proton, the ≡Si—HH—Si≡+≡Si—OHHO—Si≡ complex provides a simple explanation for reversible switching with specific electrochemical reactions that can be assigned directly to the state transitions observed in the current-voltage response.

In the manufacturing methods discussed herein, a thermal anneal in reducing ambient applied after SiO₂ deposition is more effective in reducing electroformation voltage than when the reducing anneal is performed at a later point in the fabrication process. This type of anneal after deposition is referred to as a post deposition anneal (PDA). While PDA is preferred, other embodiments may utilize reducing anneal at other times in a fabrication process. For SiO₂ materials with high as-deposited point defect concentrations, a reducing anneal that passivates the defects helps preserve the as-deposited defect concentration so that more defects are available later in the process flow when the device is exposed to the electroformation process.

Dielectric layer PDA is a process in microelectronics fabrication used to improve the insulating quality of the dielectric, although it is typically done in N₂ or O₂ ambient to densify the material, which can remove point defects and other bulk and interfacial defects. Forming gas (reducing) anneal is typically done after forming the gate structure in metal-oxide-semiconductor field effect transistors (MOSFET), and after each metallization layer is completed.

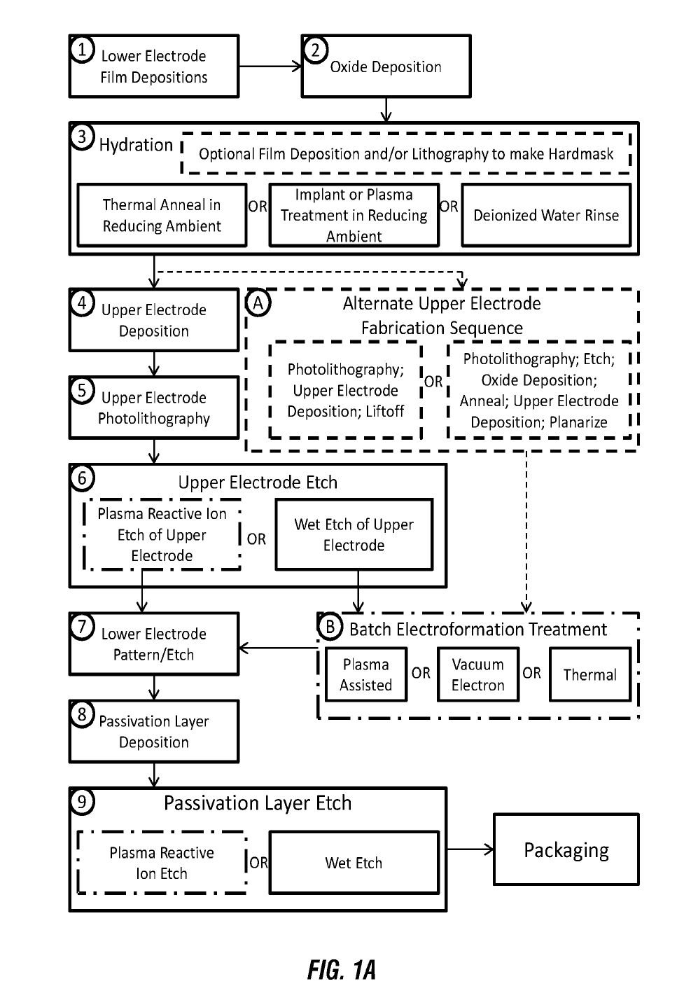

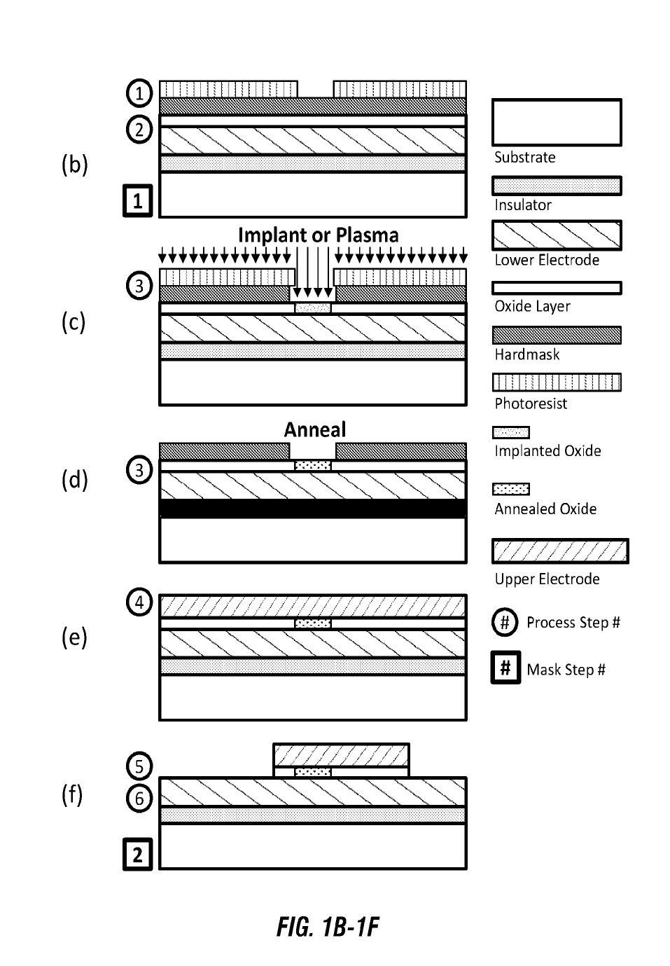

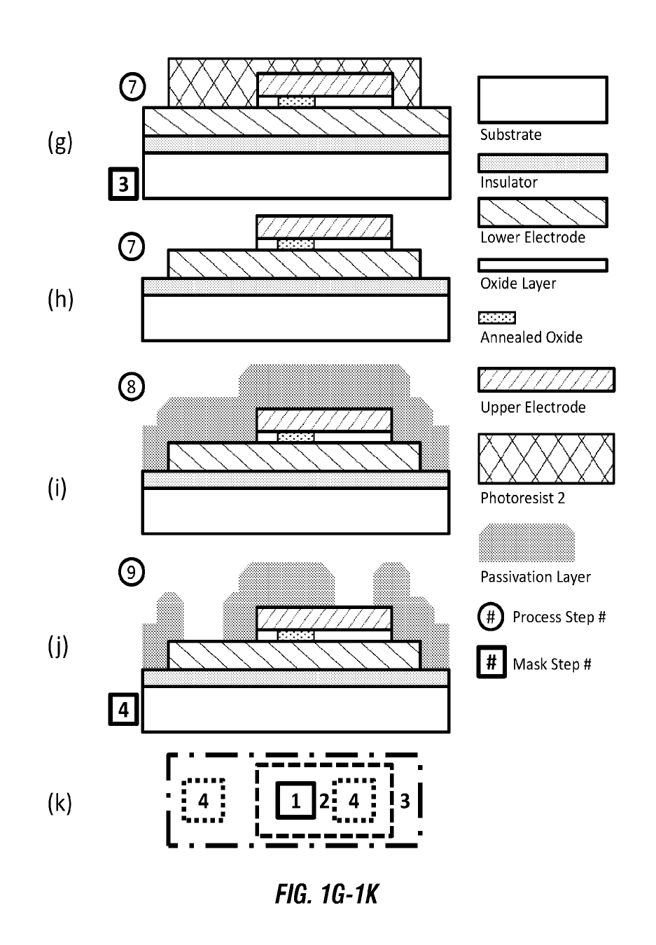

FIG. 1A shows a flow diagram of an example process flow for methods of manufacture discussed herein. Dashed boxes indicate alternative fabrication methods. Dash-dot boxes indicate processes where batch electroformation can be accomplished. FIG. 1B-1K is an illustrative embodiment a schematic corresponding to the process flow shown in FIG. 1A. In Step 1, lower electrode thin films are deposited. If silicon is used as the lower electrode, the surface can be treated by dipping the substrate in a dilute (100:1) deionized (DI) water:hydrofluoric (HF) acid solution, followed by DI water rinse and dry in N₂, to remove the native oxide from Si surfaces and terminate the surface with Si—H groups.

The oxide deposition process in Step 2 can be wet or dry thermal oxidation, physical vapor deposition, reactive sputter deposition, electron-beam evaporation, low pressure chemical vapor deposition, plasma enhanced chemical vapor deposition (PECVD), spin-coat and cure, or any suitable deposition method. Although not required, if the deposition is done at low temperature (<˜200 C), for example using e-beam evaporation, PECVD, sputter deposition, or spin-coat and cure, then a large amount of H is likely to remain at the oxide/Si interface (when Si is used as the lower electrode and is treated with an HF dip), which will promote as-deposited hydration of the oxide layer.

In Step 3, the hydration process can be applied to the blanket oxide layer, or, alternatively, to a select region of the oxide layer by deposition, pattern and etch of a hardmask. Use of the optional hardmask provides the opportunity to expose only certain regions of the oxide layer to the hydration process. In some embodiments, hydration of the oxide layer, can be accomplished using thermal anneal in an ambient containing H₂, D₂, H₂O, D₂O, NH₃, or a combination thereof. In other embodiments, a plasma treatment in an ambient containing H₂, D₂, H₂O, D₂O or NH₃ can be done in a plasma reactor. Plasma reactors are used in the microelectronics industry for reactive ion etch (RIE), photoresist stripping, thin film deposition, and other routine processes. When applying a plasma treatment at this point in the process flow, it is desirable to use a non-etching and non-depositing plasma chemistry, which will be the case for a plasma generated using the above ambient gases. Because the plasma treatment can be done at low temperature, the thermal effects of the hydration treatment can be de-coupled from the chemical effects due to the reducing ambient.

In addition, rinse in DI water and room temperature drying in N₂ can be used to hydrate the oxide surface, where the rinse promotes a large number of Si—OH groups terminating the oxide surface. The electroformation of thermal oxide layers can proceed with much higher yield when a DI rinse is used, as compared to when a DI rinse is not used.

In some embodiments, upper electrode fabrication may proceed using Steps 4-6. An upper electrode may be deposited in Step 4 utilizing any suitable deposition method, and the upper electrode may be patterned, such as by photolithography, in Step 5. Upper electrode fabrication may be completed by etching the upper electrode in Step 6. In some embodiments, a plasma-assisted reactive ion etch can be used to provide batch electroformation by charging the upper electrode positive during the etch, as indicated by the dash-dot box. This charging during RIE and other plasma treatments is known in the microfabrication industry as the “antenna effect.” The charging of the upper electrode produces a voltage across the upper and lower electrodes enabling the electroformation process to be accomplished in the memristive device without need for direct electrical connection.

In other embodiments, the upper electrode may be etched using wet etching. However, if wet etching is utilized, a batch electroformation treatment may be necessary as discussed in further detail below.

Alternative upper electrode fabrication methods are discussed in Step A as indicated by the dashed boxes. In one embodiment, upper electrode fabrication may involve a sequence of photolithography, upper electrode deposition and liftoff. In another embodiment, upper electrode fabrication may involve a sequence of photolithography, etch, oxide deposition, anneal, upper electrode deposition, and planarization. In addition to the fabrication sequences discussed above, any suitable electrode deposition and/or patterning techniques can be utilized, such as photolithography, electroplate the metal electrode, and photoresist removal.

If a wet etch or an alternative upper electrode fabrication sequence is used to pattern the upper electrode, a batch electroformation treatment may be necessary to form the memristive device in Step B. Batch electroformation may be completed using either a plasma treatment, a vacuum electron treatment, or a thermal treatment. The plasma treatment at this point in the process can be a non-etching and non-depositing plasma done in a reducing ambient including H₂, D₂, H₂O, D₂O or NH₃. Alternatively, because the primary reason for the plasma treatment at this point in the process flow is to charge the upper electrode and develop an electroforming voltage across the two electrodes, the plasma ambient can be an inert ambient including He, N₂, O₂, Ar or other noble gases, and the plasma conditions can be controlled so that little or no sputter-etching occurs.

The vacuum electron treatment will charge the upper electrode negative instead of positive (as with the plasma treatment), but will produce the same antenna effect and charging that lead to batch electroformation. Vacuum electrons can be created under low pressure conditions <1 milli-Torr by running a current through tungsten wire, for example, or by using a thermionic cathode, a cold (field emission) cathode, or any other vacuum electronic method. A positive bias on the substrate, or on the substrate chuck, can be used to direct the vacuum electrons towards the upper substrate surface.

The thermal treatment lowers the activation energy of electroformation, and can be used either in conjunction with a plasma or vacuum electron treatment, or with a direct electrical connection to promote electroformation at low voltage. The thermal treatment may be applied using infrared radiation from a tungsten-halogen lamp, for example, as well as by using radiation in other parts of the electromagnetic spectrum, or other known methods.

Both the vacuum electron treatment and the thermal treatment can be applied either globally to the substrate or locally to “direct write” devices, such as for example using a scanning tunneling microscope (STM) as the vacuum electron source or a scanned laser as the thermal energy source.

Step 7 patterns and etches the lower electrode. After deposition of the passivation layer in Step 8, openings are etched into the passivation layer in Step 9 to expose conductive interconnect lines for subsequent packaging. If a reactive ion etch is used to etch the passivation layer, this can also perform the batch electroformation process similar to when RIE is used to pattern the upper electrode. However, if wet etching is utilized, the memristive device should have been previously electroformed in Step 6 or Step B.

There are three key points in the process flow where batch electroformation can be done (as represented by the dash-dot outlines in FIG. 1): during upper electrode etch using plasma RIE (Step 6); after upper electrode patterning is complete using various electroformation options (Step B); and during etch of openings in the passivation layer with plasma RIE (Step 9).

It has been determined that using both a hydration step of thermal anneal in reducing ambient and RIE of the upper electrode results in the lowest electroformation voltage, indicating an interaction between these two processes. Using only the RIE of the upper electrode can reduce the electroformation voltage to ˜10-15V, whereas use of both post-deposition anneal (PDA) in 4% D₂/N₂ and RIE of the upper electrode further reduces the electroformation voltage to ˜5-8V.

Manufacturing, packaging and operational limitations associated with other devices are overcome by the devices and methods discussed herein. The process treatments discussed herein enable operation in air, reduced power requirements, smaller device size, and a batch conditioning process compatible with high-throughput, low-cost commercial microelectronics fabrication.

While high point-defect densities in the active oxide material are needed to form bulk memristive devices at low voltage, high defect density in the form of “pin-holes” and other structural defects can cause excessive leakage current and device short circuit failures. As a result, the oxide deposition conditions and post-deposition anneal process settings should be tuned to achieve low pin-hole defect density while preserving high point-defect concentration. Evidence is presented to demonstrate that high point-defect concentration is preserved, while pin-holes and other structural defects are suppressed by proper control of memristive material deposition conditions and use of, for example, a 5-minute post-deposition anneal (PDA) with 4% D₂ in N₂ at 400 C. An ambient comprised of 4% H₂ in N₂ is also an effective treatment to: reduce the power requirement for conditioning (or electroforming) the devices; preserve the as-deposited point-defect concentration; enable device formation within the silicon oxide bulk regions; and allow integration with an effective passivation layer for operation in air.

A primary limitation of other memristive devices is the conditioning process that must be used to electroform the device. The electroforming process must be applied to each device before reversible switching can be achieved. After this one-time electroforming process, the device can then be programmed and used as a nonvolatile memristive device. Making physical electrical contact to millions or billions of devices on a single substrate, typically a 200 mm-diameter (or larger) Si wafer, during the manufacturing process is simply not viable for manufacturing since it cannot be done with acceptable throughput (units of throughput are wafers processed per hour). As a result, the electroforming process for these devices would likely be done after the substrate is fabricated, cut into chips and packaged. Although this can be done with acceptable throughput in conventional memory devices such as those using EEPROM technology (Electrically Erasable Programmable Read-Only Memory), the power requirement to electroform the silicon oxide memristive device results in the use of larger programming transistors, wider metal interconnect lines, and larger isolation diodes, all of which lead to larger device footprint.

To overcome these issues encountered with other devices, various methods to enable large-area device electroformation across an entire substrate are taught herein: use of a vacuum electron source (applied either globally across the substrate or only in selected areas); use of thermal energy (applied either globally across the substrate or only in selected areas); and use of a plasma source. Each of these methods allow all devices present on a large-area substrate to be electroformed simultaneously using a single processing step during the wafer fabrication process flow, thereby eliminating the need to make physical, electrical contact to each device during the electroformation process. This also eliminates the need to perform a time-consuming, high-power conditioning process as part of device packaging. Furthermore, since the device conditioning process requires higher voltage and current as compared to device programming and read, by doing the conditioning process in wafer form, the size of the programming transistors, metal interconnect lines and isolation diodes can be reduced to support a lower power requirement, all of which lead to reduced device footprint and higher device density.

In one embodiment, the memristive material may be silicon oxide (SiOₓ). A silicon oxide memristive device and method of manufacture for the device is discussed in further detail below. An active silicon oxide layer can be grown by wet or dry thermal oxidation of silicon, or deposited using physical vapor deposition, reactive sputter deposition, electron-beam evaporation, low pressure chemical vapor deposition, plasma enhanced chemical vapor deposition, spin-coat and cure, or any other suitable deposition method. In some embodiments, the memristive device can be formed inside a contact hole, or inside a vertical interconnect architecture (via) using conventional manufacturing methods.

A conductive substrate can be used to form the lower electrode, or the lower electrode can be formed by metal thin film deposition on an insulator, pattern and etch. Electrodes can be comprised of doped Si, implanted Si, doped poly-silicon, metal silicides, and metals such as W, Ta, WN, TaN, TiW, TiN, Pd, Al, other standard interconnect metals, and combinations thereof. If Cu or Au electrodes are used, a barrier metal such as those above should be used to protect from electromigration and diffusion of metal ions into the memristive material. In some embodiments, the patterned lower electrode can be embedded into the insulator using trench etch, metal deposition, and chemical mechanical planarization, or can be deposited, patterned and etched to form features entirely above the insulator layer.

Passivation layer materials can include Si₃N₄, SiOₓN_{y}, SiNₓC_{y}, SiC, epoxy-based photoresist and numerous polyimide and epoxy materials.

Post deposition anneal (PDA) of silicon oxide memristive materials may utilize deuterium diluted in N₂, Ar or other inert gases can be done over a wide temperature range from approximately 100 C to 700 C, with deuterium concentrations ranging from ˜4% up to the industry-standard concentration of 10-15%. Water vapor, H₂, deuterated water vapor or ammonia can potentially be used instead of deuterium for the post deposition reducing anneal.

Device electrode arrangements can include a vertical architecture where each of the lower electrode, oxide, and upper electrode are on separate layers, or a planar architecture with the two electrodes adjacent to each other on the same layer and separated by the oxide. A vertical or horizontal edge, sidewall, or surface can be formed and used to support the active memristive device, or the device can be formed in the bulk material between the electrodes. In both cases, post-oxide-deposition anneal with deuterium consistently lowers the electroformation voltage to ˜5V.

Devices across an entire substrate can be electroformed during the wafer fabrication process flow using: a vacuum electron source; a thermal source; or a vacuum plasma source. Devices in selected areas of a substrate can be electroformed using: a vacuum electron source; or a thermal source.

FIGS. 1B-1K show an example process flow implementing Steps 1-9 of FIG. 1A with a hardmask to only treat select regions of the oxide layer with the hydration process. In Steps 1 and 2, an insulator layer is deposited onto a substrate, followed by deposition of a conductive lower electrode, oxide layer, hardmask and photoresist layer. An opening is patterned in the photoresist, followed by hardmask etch in Step 3. In some embodiments, the photoresist layer can be used as a mask for low-temperature treatments such as ion implant or plasma exposure. The implant and/or plasma treatments are used to slightly damage, or weaken, the oxide layer in exposed regions, thus promoting enhanced hydration during the subsequent thermal anneal. Water and other defects are known to diffuse more rapidly in porous oxide materials or materials that have been damaged, or weakened. Using a hardmask to only treat select regions of the oxide layer allows untreated regions of the oxide layer to retain the as-deposited insulator properties. The photoresist layer must be removed prior to thermal reducing anneal at temperatures ranging from 200 C to 450 C (when metal lower electrodes are used) or as high as 1000 C (when lower electrode is polysilicon, for example).

The hardmask can then be removed and top conductive electrode deposited in Step 4, followed by pattern and etch in Steps 5 and 6. The lower electrode is then patterned and etched in Step 7, followed by passivation layer deposition (Step 8) and pattern and etch (Step 9) to complete the process. The 4 mask layers used for this example process flow are shown in a top-down view in FIG. 1K.

### EXPERIMENTAL EXAMPLES

The following examples are included to demonstrate particular aspects of the present disclosure. It should be appreciated by those of ordinary skill in the art that the methods described in the examples that follow merely represent illustrative embodiments of the disclosure. Those of ordinary skill in the art should, in light of the present disclosure, appreciate that many changes can be made in the specific embodiments described and still obtain a like or similar result without departing from the spirit and scope of the present disclosure.

Switching Mechanisms in SiO₂ Memristor Devices

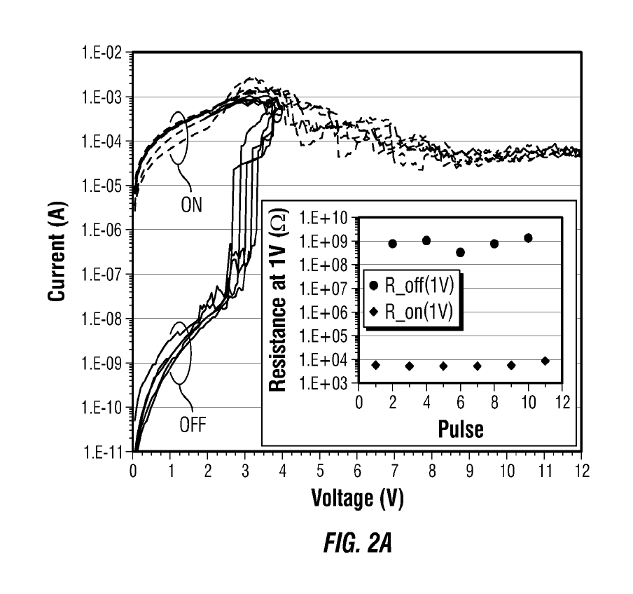

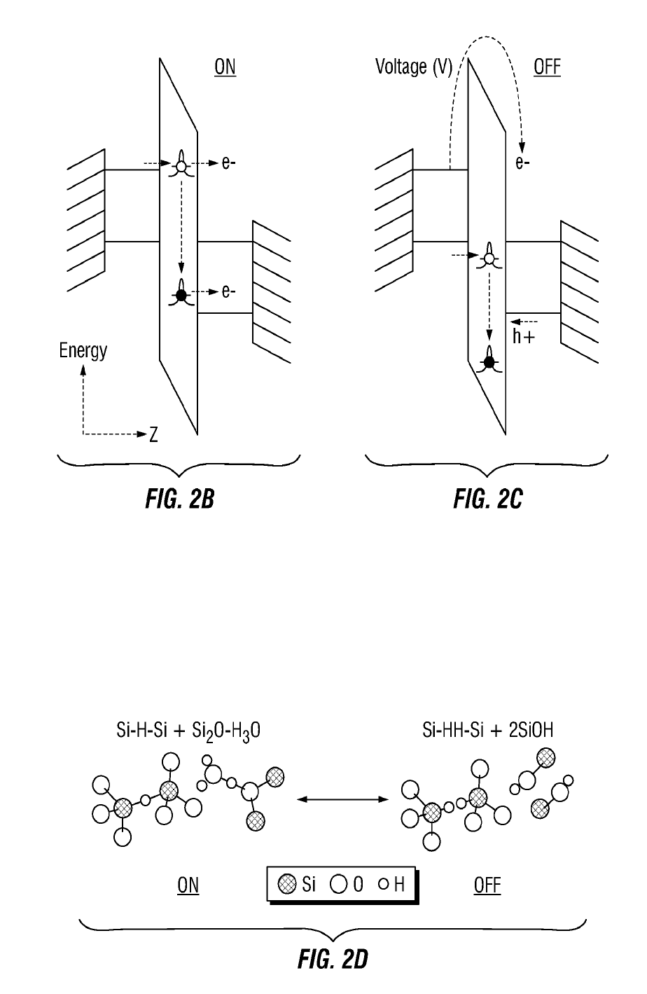

FIGS. 2A-2D summarize the device current-voltage response (FIG. 2A), charge transport in the ON (FIG. 2B) and OFF (FIG. 2C) states, and the reversible switching mechanisms (FIG. 2D) described above. FIG. 2A shows a typical device current-voltage response. Device state is typically read at ˜1V, with OFF-state devices having current of ˜1 nA at 1V and ON-state devices having current of ˜100 uA at 1V. For OFF-state devices, the turn-ON state transition occurs at 2.5 to 3.5 V. Device turn-ON in this device was programmed using a forward/reverse sweep to 4V. Device turn-OFF was programmed using a forward voltage sweep to 12V. The inset of FIG. 2A shows the resistance of the ON and OFF states after each programming pulse, indicating an ON/OFF ratio>10⁴ for this device. FIGS. 2B-2C show simplified energy band diagrams and charge transport mechanisms in ON (defect-assisted tunneling) and OFF (Poole-Frenkel conduction) states. FIG. 2D shows the reversible switching mechanisms presented in reaction (8) above, where electrically-active Si—H—Si defects in the ON state account for the high conductivity and electrically-inactive Si—HH—Si defects in the OFF state result in low conductivity. The ON-state current consists of trap-assisted tunneling where the energy levels of the Si—H—Si defect couple electrically with the electrodes. In the OFF state, Poole-Frenkel or other leakage current components dominate.

In the OFF state, Si—HH—Si defects trap electrons in a neutral charge state and do not participate in charge transport until a bias of 2.6 V is applied, which corresponds to the difference in switching charge-state energy levels of 2.6 eV in this defect. As described above, this leads to de-trapping of the electron (equivalent to capture of a hole) and the potential for proton emission and conversion to the conductive Si—H—Si defect. The emitted proton is then available for uptake by the water molecule bonded into the SiO₂ network as the 2SiOH defect, which transforms this defect to the Si₂O—H₃O defect to finalize the turn-ON transition. The 2.6 eV required to initiate the turn-ON transition corresponds closely to the observed turn-ON transition in the current-voltage response at ˜2.5V (FIG. 2A), thus allowing the proton emission reaction (4) to be assigned to the turn-ON transition in the current-voltage response.

In the ON state, the Si—H—Si defect can effectively trap and de-trap electrons in stable negative and neutral-charged states, respectively. As such, when an electron is trapped, its charge compensates the positive-charged H₃O⁺ defect so that overall charge neutrality is maintained in the stable dipole complex. As current increases through the defect complex, Joule heating and/or other decomposition pathways eventually lead to the collapse of the dipole and an electrochemical reaction where a proton from the H₃O⁺ defect is transferred to the Si—H—Si defect to accomplish device turn-OFF. This turn-OFF transition is similar to the reaction of a Si—H⁻—Si defect and H⁺, which is understood by density functional theory calculations to result in formation of the Si—HH—Si defect and the release of ˜3 eV of energy. With an activation energy barrier of ˜1.5 eV for reaction of H₂O with the SiO₂ network, the released energy of ˜3 eV is more than enough to drive the turn-OFF reaction to completion.

The OFF-state defect complex described in FIG. 2D can be viewed as a H₂ molecule bonded into an oxygen vacancy defect and a H₂O molecule bonded into the SiO₂ network. Alternatively, the defect complex can be viewed as being two H₂O molecules bonded into two oxygen vacancy defects with the two OH groups segregated on one side and the two H atoms on the other side. The reversible reaction (8) above is thus accomplished by the transfer of a single proton between the two defects in the complex, with both reactions being understood to be energetically feasible based on the density functional theory calculations reported in the technical literature.

Post Deposition Anneal

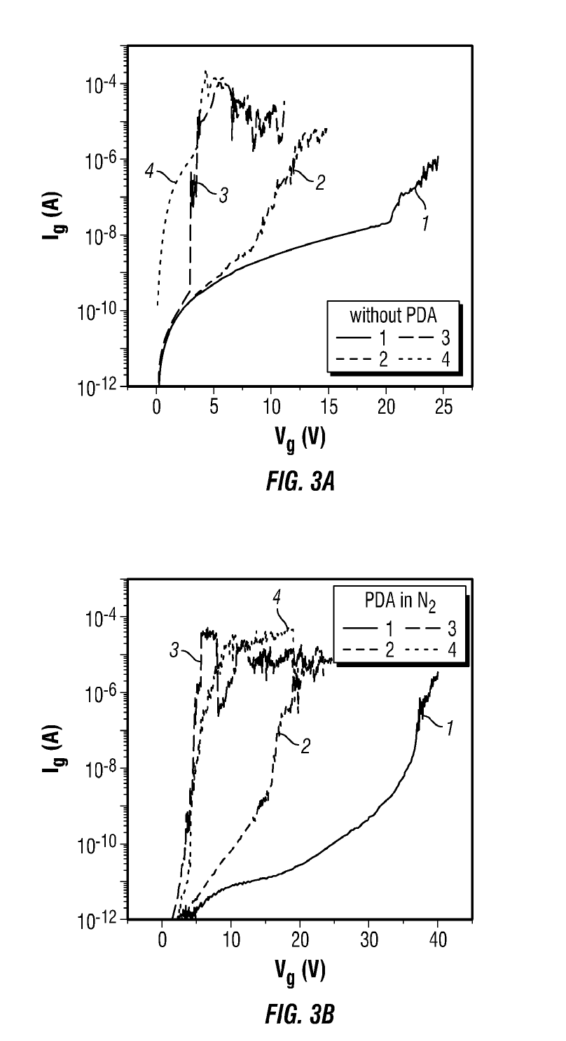

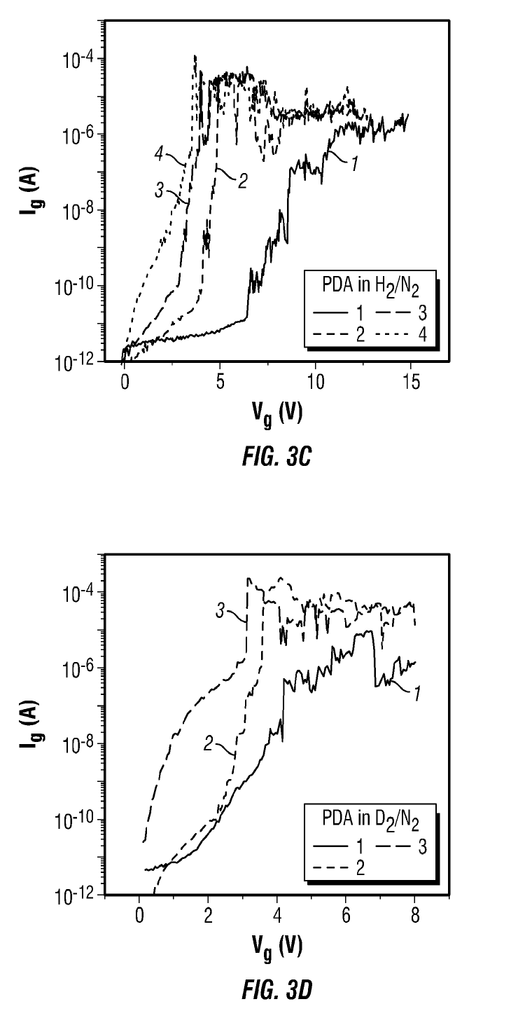

Comparison of electroforming voltage (V_{ef}) of devices with post-deposition anneal (PDA) in different gas ambient is presented in FIGS. 3A-3D. Here, we define V_{ef} as the voltage where there is a sharp increase in gate leakage current with fluctuations of ˜1 μA. For the control devices (no PDA), V_{ef} is around 25 V as seen in FIG. 3A. With PDA in N₂ ambient, V_{ef} is significantly increased to near 40 V as in FIG. 3B. This suggests that N₂ PDA effectively and significantly reduces defect centers in the oxide bulk, lowers leakage current and improves oxide quality, which then makes it more difficult to achieve soft breakdown and initiate device electroformation at low voltage. For devices with PDA in H₂/N₂ or D₂/N₂ ambient, V_{ef} is significantly reduced, especially for devices with PDA in D₂/N₂. The V_{ef} is reduced to around 10-14V in devices with H₂/N₂ anneal and to 4-8V for devices with D₂/N₂ anneal.

After PDA in H₂/N₂ (or D₂/N₂) ambient, Si—H (or Si-D) bonds are expected to form in the SiOₓ layer, thus helping to preserve the as-deposited defect concentration by passivating oxygen vacancy defects so high defect concentrations are present when the device is subsequently electroformed. Experiments showing that D₂ anneal consistently reduces electroformation voltage in devices formed in a sidewall architecture have been repeated and verified several times. Performing a post-oxide-deposition anneal in deuterium reduces electroforming voltage to less than 10V, and this benefit was found to remain after subsequent processing and thermal treatments were performed, where low forming voltage is observed even after upper electrode fabrication, dielectric etch, backside wafer Al deposition, and post-fabrication treatments in forming gas, pure N₂ at 500 C, or no anneal. These results indicate that Si—HH—Si (or Si-DD-Si) defects are effective precursors for device electroformation.

Bulk devices without a sidewall have been fabricated using electron-beam evaporation to deposit the active oxide layer, D₂/N₂ anneal, and dry etch to form the top electrode in TaN. Bulk devices have also been fabricated using a liftoff process to form the top metal electrode, followed by coating with an SU8 epoxy-based photoresist passivation layer and patterning to open the passivation layer only near the center of each top electrode to allow probe testing. Operation of these devices in air has been verified and repeated on several proof-of-principle test structures.

In situ device electroformation of electron-beam-deposited SiO₂ during dry etch of a TaN upper electrode layer has been observed and verified in three experiments to date on more than twelve test structures with n+ silicon substrate as lower electrode.

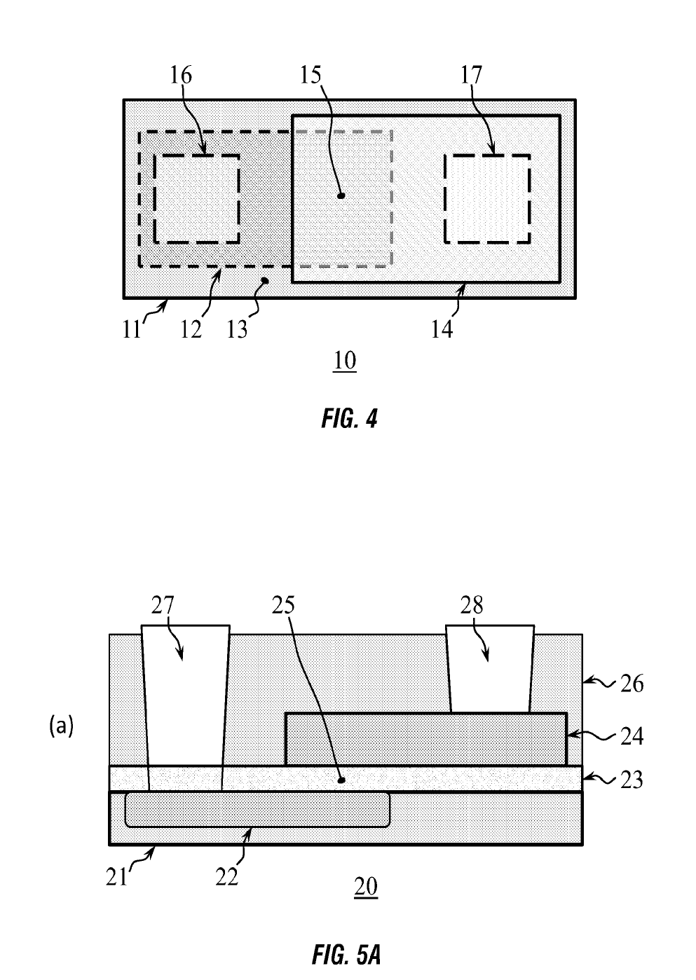

FIG. 4 is the top down view representation of an embodiment of a memristive device 10 with substrate 11 having a first doping type and area 12 formed in the substrate having a second doping type where areas of second doping type form a first conductive electrode. A first layer 13 of memristive material is formed over substrate 11 and region 12, followed by thermal anneal in reducing ambient. A second layer of conductive material is deposited over first layer, patterned and etched using, for example, plasma-assisted dry etch to form second electrode 14 and overlap region 15. A third layer of insulating material is deposited and openings 16 and 17 are made to regions 12 and top electrode 14.

FIGS. 5A and 5B are cross-section drawings of one embodiment of the memristive device described in FIG. 4 with substrate 21 having a first doping type. FIG. 5A shows a cross-section drawing of memristive device unit cell showing lower electrode 22, memristive layer 23, overlap region 25, top electrode 24, passivation layer 26, and passivation openings 27 and 28 for electrical contact. In FIG. 5B, opening 29 is patterned into layer 23 prior to deposition of passivation layer 26 to eliminate the potential for water or oxygen to diffuse into active layer 23 from passivation opening 27. Regions within substrate 21 having a second doping type form first conductive electrode 22, with doped region 22 being formed using, for example, pattern with photoresist, ion implant, photoresist removal and anneal. A first layer 23 of memristive material is formed over substrate 21 and region 22, followed by thermal anneal in reducing ambient using, for example, 4% D₂ in N₂ for 5 minutes at 400 C, in accordance with the process flow shown in FIG. 1A but without use of the optional hardmask in FIG. 1A, Step 3. A second layer of conductive material is deposited over first layer, patterned and etched to form second electrode 24 and overlap region 25. A third layer 26 is deposited insulating material having low permeability to water and oxygen in order to protect device active region 25 from ambient contamination. Patterning and plasma-assisted etch, for example, are used to form openings 27 and 28 to lower electrode 22 and upper electrode 24, respectively.

The memristive material used for active device layer 23 can be silicon oxide, SiOₓ, where 1≦x≦2, for example, grown by wet or dry thermal oxidation of silicon, or deposited using physical vapor deposition, reactive sputter deposition, electron-beam evaporation, low pressure chemical vapor deposition, plasma enhanced chemical vapor deposition, or spin-coat and cure. Active device layer 23 thickness can be greater than or equal to 5 nm and less than or equal to 200 nm. In other embodiments, memristive layer may be equal to or greater than 1 nm.

The thermal treatment of first layer memristive material 23 can be a reducing anneal at temperatures ranging from 100 C to 700 C and time periods from 30 seconds to 30 minutes. The anneal ambient may be any suitable ambient containing hydrogen or deuterium. For example, the anneal ambient may comprise deuterium (D₂), hydrogen (H₂), water vapor (H₂O), ammonia (NH₃) or deuterated water vapor (DₓH₂₋ₓO (0<x≦2) diluted from 1% to 20% in inert gas (e.g. N₂, He or Ar), or a combination thereof. The anneal ambient effectively passivates point defects such as oxygen vacancies within the bulk oxide material with the thermal decomposition products. Oxygen vacancy defects are passivated by forming Si—H (or Si-D) and/or Si—OH (or Si—OD) bonds within the defect.

The substrate material can be any suitable semiconductor material, such as silicon, Si, silicon carbide, SiC, gallium arsenide, GaAs, indium phosphide, InP, or the like. The substrate may provide a doped region 22 accomplished by any suitable implant or diffusion methods. The substrate can, for example, be lightly-doped n- or p-type, with regions 22 being heavily-doped p- or n-type, respectively. In addition to having a first conductive electrode 22, substrate 21 can have semiconductor devices such as transistors, diodes, resistors, or other circuit components, and the memristive device can be connected to these other devices through interconnects formed in region 22, or by metal interconnects making contact to exposed regions of lower electrode 22 and upper electrode 24 through openings 27 and 28, respectively.

Conductive layer 24 can be any suitable conductive or semiconductive material. Nonlimiting examples of the conductive layer may include polysilicon, n-type doped polysilicon, p-type doped polysilicon, tungsten, titanium-tungsten alloy, titanium-nitride alloy, tantalum, tantalum-nitride alloy, palladium, aluminum, copper, gold, platinum silicide, titanium silicide, tantalum silicide, cobalt silicide, nickel silicide, tungsten silicide, a combination thereof, or the like.

If Cu or Au electrodes are used, a barrier metal between the memristive material and the electrode may be used in some embodiments to protect from electromigration and diffusion of metal ions into the active device.

Depending on the material, upper electrode 24 can be patterned using photolithography and etched using either wet or dry etch chemistry. Materials such as polysilicon, Al, W, TiW, Ta, TaN, for example, can be etched using plasma-assisted reactive ion etch (RIE), whereas Cu and Au can typically only be etched using wet chemistries since they form no volatile etch products. Any suitable dry and wet etch chemistries and processes for these materials may be uitilized. As described below, a plasma-assisted etch, a treatment with non-etching plasma, or treatment by a vacuum electron source can be used to provide in situ device electroformation in a batch process.

Layer 26 can be formed from any suitable insulating or passivating material(s). Nonlimiting examples may include Si₃N₄, SiOₓN_{y}, SiC, SiNₓC_{y}, borosilicate glass, BSG, phosphosilicate glass, PSG, boro-phosphosilicate glass, BPSG, polyimide, epoxy-based photoresist and epoxy, as needed to protect the device from ambient contaminates by having low permeability to oxygen, water and other contaminates in air. Openings 27 and 28 can be formed simultaneously by using standard photolithography and etch methods with high etch selectivity to electrode 24 and electrode 22.

Electrode 22 can connect the device to other devices formed in substrate 21, or can be contacted through opening 27. Typical next steps in microelectronics fabrication is to fill openings 27 and 28 with a suitable contact metal, W for example, and deposit and pattern a plethora of insulator and conductive layers to form electrical interconnects to other substrate 21 devices and external circuit components.

The spacing between active device overlap region 25 and opening 27 is preferably large enough to avoid dielectric breakdown and other electric-field-driven failure modes from occurring in layers 26 and 23. In another embodiment, shown in in FIG. 5B, opening 29 is patterned into layer 23 prior to deposition of passivation layer 26 to eliminate the potential for water or oxygen to diffuse into active layer 23 from passivation opening 27. Layer 23 is patterned and etched to form opening 29 prior to layer 26 deposition so that all layer 23 material is removed from around opening 27 and opening 27 is formed entirely in layer 26. Removal of layer 23 from around the wafer edge can also be used to allow electrical contact to electrode 22 during device conditioning, as described further below.

In another embodiment, layer 23 is patterned and etched after forming electrode 24, and where an opening is provided to expose an edge of electrode 24, thereby forming a sidewall (not shown) in layer 23 between electrodes 22 and 24. In this case, electrode 24 is used as an etch hardmask for either wet- or plasma-based etch chemistries.

In another embodiment, substrate 21 is an insulating material or a substrate with an insulating layer, with electrode 22 being formed by dielectric etch, metal deposition, and chemical mechanical planarization. Alternatively, electrode 22 could be formed on top of the substrate using deposition, pattern and etch of a conductive layer.

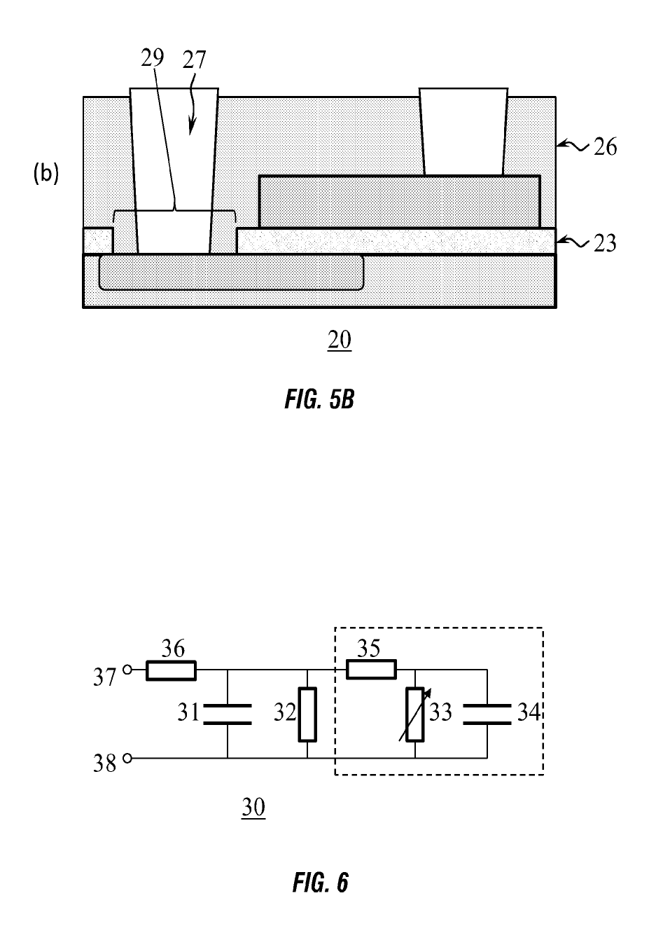

FIG. 6 shows a circuit schematic representation of the memristive device in FIG. 5A showing device capacitance and leakage resistor in parallel with memristive device (enclosed by dashed box) having variable resistance and series resistance from active device region to contact terminals. Capacitor 31 accounts for the capacitance between electrode 24 and electrode 22, defined by overlap region 25. Resistor 32 accounts for bulk and other parasitic leakage currents through the device. Variable resistor 33 represents the active region within the memristive material that produces reversible switching, with resistance depending on a previous voltage or current programming pulse. Capacitor 34 accounts for the fundamental switching time constant of the device. Resistor 35 is the series resistance of the memristive device in regions between the active region and the electrodes. Resistor 36 accounts for parasitic series resistance in the electrodes to device terminals 37 and 38.

Only small areas are believed to be involved in device switching, where filament-like structures formed by electrical stressing of the dielectric can be switched reversibly between high and low resistance states. The active device region can be considered to be a weak point along the filament that is broken and reconnected to accomplish reversible switching. The cross-sectional area of the active device region is likely much smaller than FIG. 5A overlap area 25, so that the capacitance of capacitor 31 is much larger than the capacitance of capacitor 34. As a result, total device capacitance is not expected to change significantly when the device is switched between high and low resistance states. Variable resistor 33 will have resistance much smaller than leakage resistor 32 in the ON state so that it will dominate total device conductance. When the device is programmed to a fully-OFF state, variable resistor 33 will have resistance comparable to leakage resistor 32.

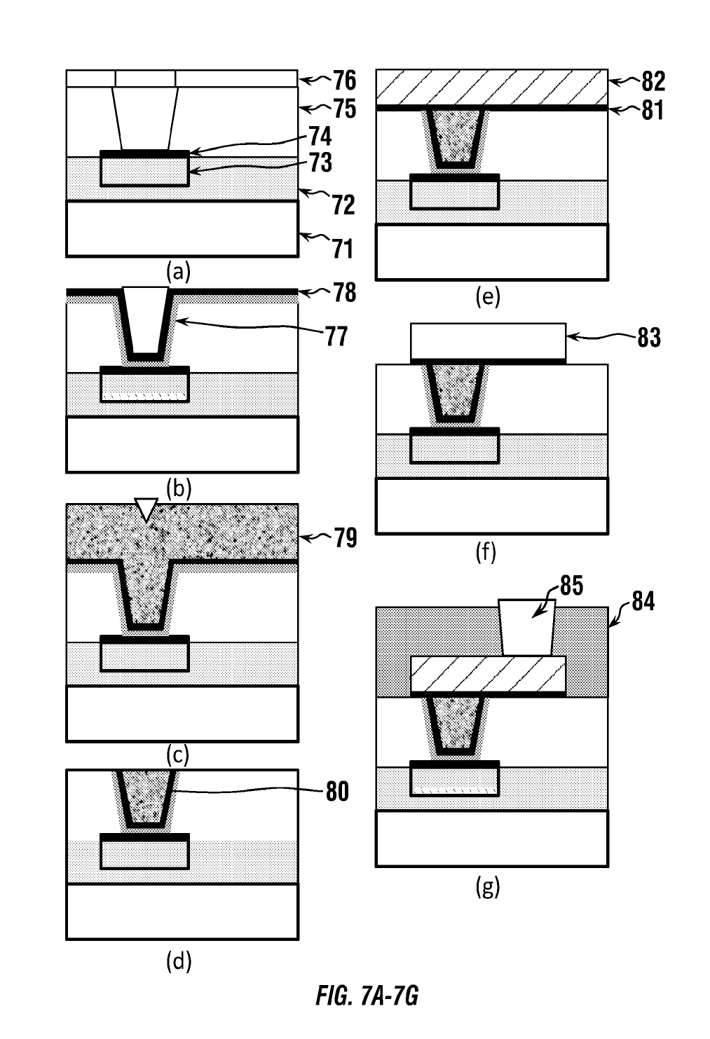

FIGS. 7A-7G show the process flow forming memristive device within a contact hole or via opening in an interlayer dielectric (ILD). Insulator layer 72 is first deposited onto substrate 71, followed by photolithography, etch, metal 73 deposition, chemical mechanical planarization, and electroplating of barrier layer 74. Insulator layer 75 is then deposited. Photoresist mask 76 is used to etch a via through insulator layer 75 stopping on metal diffusion barrier layer 74. Metal diffusion barrier layer 74 protects against metal diffusion from lower electrode layer 73 into the active oxide device layer.

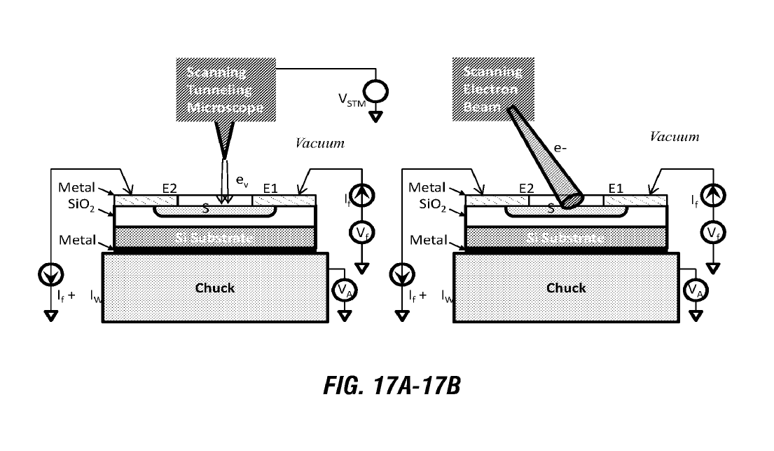

Photoresist layer 76 is stripped and a conformal memristive layer 77 is deposited as a liner onto the sidewalls of the contact or via opening. Metal diffusion barrier layer 78 is then deposited over memristive layer 77. This technology has been well-developed for physical vapor deposition (PVD) of metal barrier layers ˜50 A thick onto high-aspect-ratio vias, and extremely high precision has been obtained for these materials. Replacing the barrier metal in such a via process with a dielectric/barrier layer stack achieves the architecture shown in FIG. 17.

Via metal layer 79 is then deposited followed by chemical mechanical planarization to form conductive plug 80. Conductive barrier layer 81 and conductive layer 82 are then deposited. Photolithography and etch are used to form top conductive trace 83. Passivation layer 84 is deposited, patterned and etched to form opening 85 so as to make electrical connection to top conductive trace 83.

The architecture of FIG. 7D uses conductive plug 80 to effectively extend top conductive trace 83 down to lower electrode 73 and the device is formed in the thin, high-field region across memristive layer 77 at the bottom of the via hole. Potential issues with this approach include controlling the over-etch into barrier layer 74 and controlling memristive layer 77 thickness at the bottom of the via, but these issues can be avoided by proper optimization of the dielectric etch and the memristive layer 77 deposition processes. Plasma-enhanced chemical vapor deposition (PECVD) can be used for conformal film deposition onto high aspect ratio features as in FIG. 7B, and PECVD deposition parameters such as pressure, power, gas mixture and flow rate can be adjusted to achieve conformality values from near unity (same thickness on the sidewall as on the bottom of the hole) to near zero (no film deposited on the sidewall).

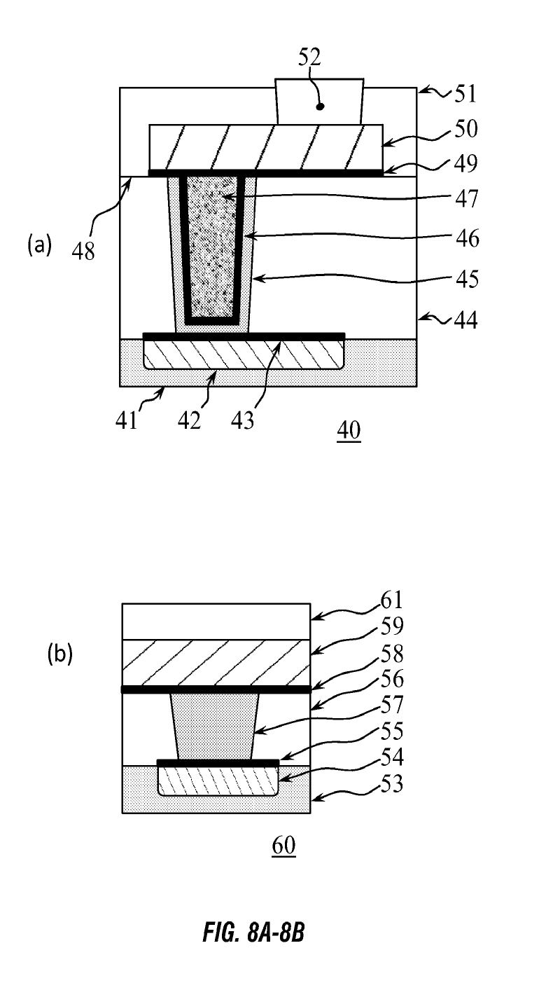

FIGS. 8A-8B show cross-sections of memristive devices formed within a contact or via. A cross-sectional sketch of the final device architecture obtained when using chemical mechanical planarization to pattern the via electrode is shown in FIG. 8A. Layer 41 is an insulator deposited on a substrate or an insulating substrate, layer 42 is a patterned conductive lower electrode, and layer 43 is a barrier metal that is deposited or electroplated onto patterned layer 42. A hole is etched into interlayer dielectric (ILD) layer 44, followed by active oxide layer 45 deposition, barrier metal 46 deposition (if necessary due to the material utilized for the electrodes), and conductive plug 47 deposition. The surface is then polished using chemical mechanical planarization down to line 48. Barrier metal 49 and conductive trace 50 are then deposited, patterned and etched, followed by deposition of oxygen and water barrier layer 51. Pattern and etch of layer 51 forms opening 52. If layers 42, 47 and 50 are Cu or Au, then layers 43, 46 and 49 are desirable to block metal ion diffusion into active memristive layer 45. Metal barrier layers 43, 46 and 49 may not be needed, if the electrode material(s) does not necessitate the desire to block metal ion diffusion, for example if layer 42 is doped Si or aluminum, plug layer 47 is tungsten, and layer 50 is aluminum.

FIG. 8B shows the resulting architecture when scaled to very small feature size. Insulating layer 53 electrically isolates conductive trace 54. Metal diffusion barrier layer 55 is electroplated onto conductive trace 54 if needed to block metal ion diffusion into memristive layer 57 embedded into insulator layer 56. Metal diffusion barrier layer 58 blocks metal ion diffusion from top conductive trace 59 into memristive layer 57. Passivation layer 61 blocks water and oxygen from the ambient from reaching memristive layer 57. In this architecture, the thickness of insulator layer 56 and memristive layer 57 can be from 5 nm to 200 nm. Because of the reduced feature size considered in FIG. 18B, no metal plug is required to extend the upper conductive trace to near the lower electrode trace as in FIG. 18A, thus simplifying the fabrication process and leading to an architecture essentially the same as that resulting from the process flow described in FIG. 1A.

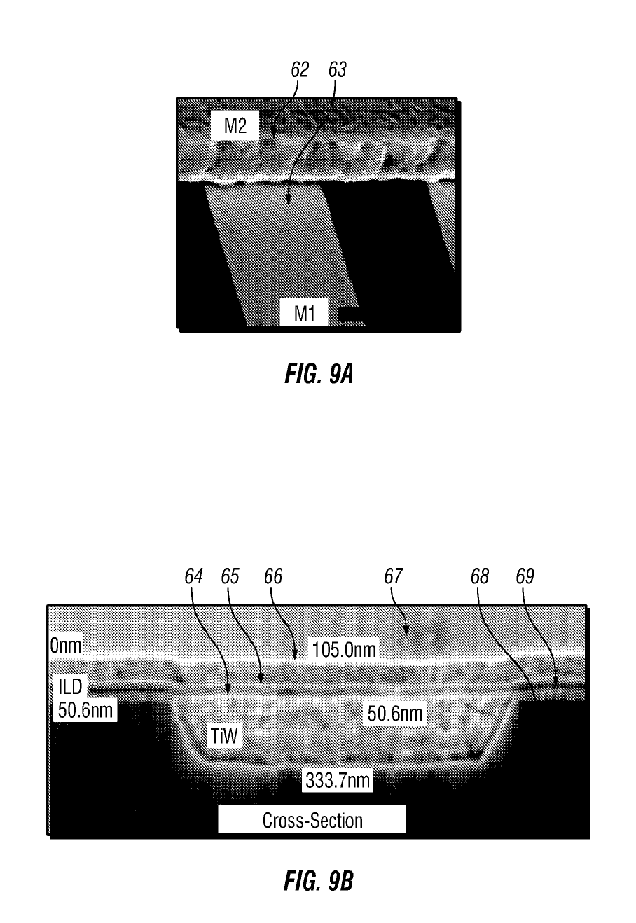

FIGS. 9A-9B show SEM images of M2 TiW/Au line 62 over planarized M1 TiW line 63 in FIG. 9A and cross-section image of planarized TiW electrode 64 with 50 nm active PECVD SiO₂ layer 65 and 100 nm TiW top electrode 66 in FIG. 19B. Fabrication of test devices has been done using a variety of architectures. Upper TiW electrode 66 provides a metal diffusion barrier to block Au diffusion from layer 67 into active SiO₂ layer 65. Lower TiW electrode 64 is embedded into SiO₂ isolation layer 68 and Si₃N₄ polish-stop layer 69 was used to maintain low step-height at the upper corners of embedded TiW electrode 64. Wet thermal oxidation of Si was used to deposit SiO₂ isolation layer 68 and low-pressure chemical vapor deposition (LPCVD) was used for Si₃N₄ polish-stop layer 69. These devices received a 350 C, 30-minute post-deposition anneal in N₂ to densify active SiO₂ layer 65.

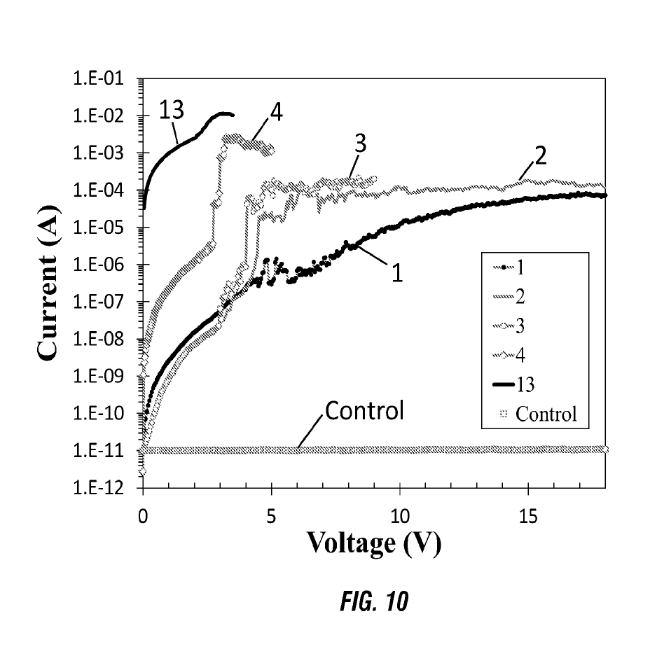

FIG. 10 shows conditioning curves for devices with sidewall (curves 1-4, 13) showing successful electroformation, and without sidewall (Control) showing no electroformation. The TiW/SiO₂/TiW devices were tested with and without a sidewall to verify that no electroforming occurs in devices (control) without a sidewall when the active oxide layer post-deposition anneal comprises a non-reducing, inert ambient. Curves 1-4 show that conditioning, or device electroformation, can be accomplished by applying a series of linear voltage sweeps. The first sweep to 18V, Curve 1, shows considerable leakage current across the sidewall, with small peaks of ˜1 uA at ˜5V. Subsequent sweeps to 18, 9 and 5V show that the large current increases occur at lower voltages. Curve 4 is indicative of an electroformed device, with a large current increase at ˜3V. After the device is electroformed, it operates as a reversible switch. The device in FIG. 10 was switched ON and OFF by applying voltage pulses of 3.5V and 9V, respectively. Curve 13 is the I-V response in an ON state, with ˜1 mA being measured at 1V for this device. An OFF state is shown by Curve 4, with ˜0.2 uA being measured at 1V, representing an ON/OFF ratio of 5000.

An adjacent test structure, without an etched sidewall, was also measured, where a sweep to 24V is shown in FIG. 10 by Curve Control. Comparison of Curve Control from the device without a sidewall to Curve 1 on the device with a sidewall demonstrates that the large increase in leakage current is the result of the sidewall.

Other memristive devices have only been successfully electroformed when the sidewall was present, which suggested that the electroformation process may be inherently an edge or surface effect. However, according to the methods discussed herein, and as shown by the data presented Table 1 and Table 2, the use of reducing anneal as a post-deposition treatment to the memristive material can significantly lower the device electroformation voltage requirement.

TABLE 1
Measured electroformation voltages from post-
deposition anneal experiment versus temperature.
Anneal time is 5 minutes for all cases.

| Anneal Ambient | 400 C. | 500 C. | 600 C. | 700 C. |
|---|---|---|---|---|
| None | | 24 | | |
| O₂ | | 23 | | |
| N₂ | 45 | 30 | 5 | 6 |
| 4% D₂ in N₂ | 4 | 5 | 6 | 9 |
| 4% H₂ in N₂ | | 16 | | |

TABLE 2
Measured electroformation voltages from post-deposition anneal experiment
versus time and temperature.

| N₂ Ambient | 400 C. | 500 C. | 600 C. | 700 C. | D₂/N₂ Ambient | 400 C. | 500 C. | 600 C. | 700 C. |
|---|---|---|---|---|---|---|---|---|---|
| 5 minutes | 45 | 30 | 5 | 6 | 5 minutes | 4 | 5 | 6 | 9 |
| 10 minutes | 40 | 20 | 10 | 20 | 10 minutes | 3 | 7 | 7 | 6 |
| 15 minutes | — | — | 20 | 15 | 15 minutes | 5 | 10 | 7 | 13 |

The process flow for these test samples was: Si wafer clean; deposit SiO₂ using e-beam evaporation; no anneal or anneal at various temperature and time in N₂, 4% H₂/N₂ or 4% D₂/N₂; sputter deposit TaN; pattern and etch in CF₄ plasma; and 30-second 10:1 buffered oxide etch (BOE).

After fabrication, waveforms comprising linear voltage ramps were applied across the device until current spikes on the order of 1 uA were observed. The voltage where current spikes of 1 uA occurred was recorded as the electroformation voltage. After subsequent linear voltage ramps, a characteristic I-V response was achieved, indicated that active device forming is complete and the device can be reversibly switched between ON and OFF states by applying voltage pulses of ˜4V and ˜8V, respectively. The state of the device is “read” by measuring the current through the device at low voltage ˜1V.

Inspection of the data in Table 1 and Table 2 show that reducing anneal in either H₂/N₂ or D₂/N₂ results in much lower electroformation voltage (V_{EF}) as compared to no anneal, anneal in N₂ only, or anneal in O₂. For N₂ anneal, increasing temperature tends to lower V_{EF} and increasing time tends to increase V_{EF}. For D₂/N₂ anneal, increasing temperature and increasing time both tend to slightly increase V_{EF}.

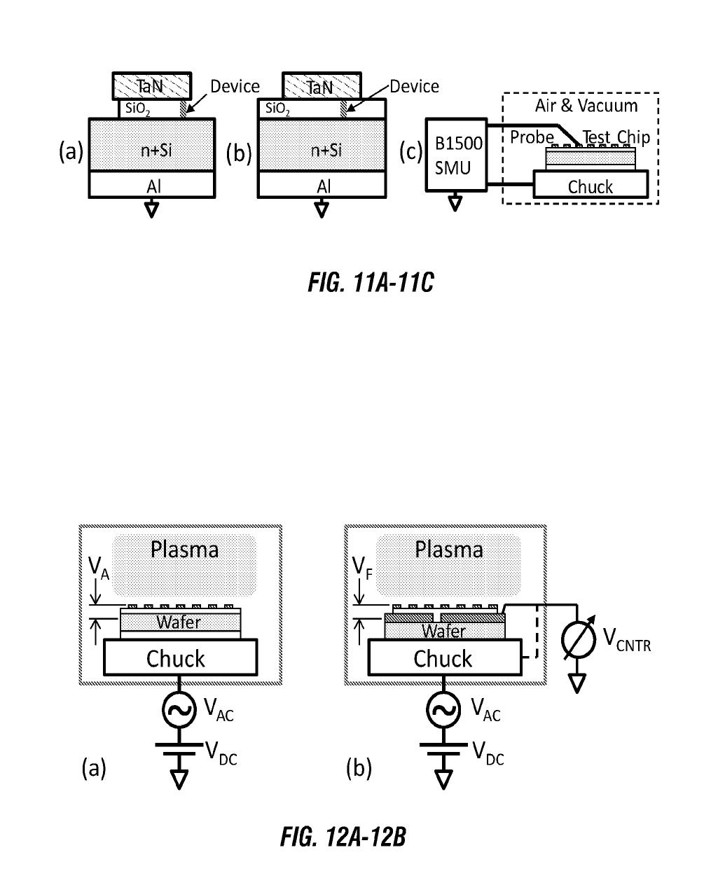

FIGS. 11A-11C show single-mask test structures with (FIG. 11A) and without (FIG. 11B) sidewall, and test set-up (FIG. 11C). Devices with TaN upper electrode, 50 nm-thick SiO₂ active layer deposited using e-beam evaporation, and n+ silicon substrate as lower electrode are represented. In some samples, a backside Al contact was used for improved electrical contact to the lower n+Si substrate electrode. These test structures were used to collect the data reported in Table 1 and Table 2, using the test set-up shown. An Agilent B1500A with high-voltage (100V) source-measure unit (SMU) was used to collect I-V data on test samples inside a vacuum probe chamber and in a probe station in air.

It has been observed during initial experimentation that PDA in reducing ambient enables device electroformation in air when no sidewall is used to support the device, as shown pictorially in the device structure in FIG. 11B without an etched sidewall. This is the first time that operation in air has been observed, and, since there is no sidewall, the device must be forming within the bulk of the SiO₂ layer.

FIGS. 12A-12B show a schematic representation of plasma reactor with (FIG. 12A) lower electrode connected to wafer chuck; and (FIG. 12B) modified configuration for improved control of forming voltage using edge connection to device lower electrode and controllable bias V_{CNTR}. Dashed line shows lower electrode connection to chuck when insulating substrate is used and V_{CNTR} is not used. Devices with TaN top electrode were etched in a reactive ion etch (RIE) system with power applied to the chuck as shown schematically in FIG. 12A. In this process, the lower electrode is connected directly to the wafer chuck through the backside Al contact. As a result of the plasma above the device, a voltage potential V_{A} is developed across the SiO₂ layer between the top TaN electrodes and the lower n+Si electrode. This is known in the art of microfabrication as the “Antenna Effect.”

The Antenna Effect is utilized to perform electroformation in situ during etch of the top electrode, or during a later step using a non-etching plasma. Because this process can simultaneously electroform all devices on a Si substrate, it is compatible with conventional, high-throughput semiconductor manufacturing equipment and fabrication process flows.

FIG. 12B shows an alternative method to connect the lower electrode terminal to a node with controllable bias V_{CNTR}, leading to improved control of forming voltage V_{F} using an edge-ring connection to device lower electrode. Contacting wafers using an edge ring is common in microfabrication processes such as electroplating and other thin film deposition methods, and can be applied here to make an independent connection to the device lower electrode. As shown by the dashed line in FIG. 12B, the edge-ring can be connected directly to the chuck when insulating substrates are used to bypass V_{CNTR}, thus providing the same connection as in FIG. 12A.

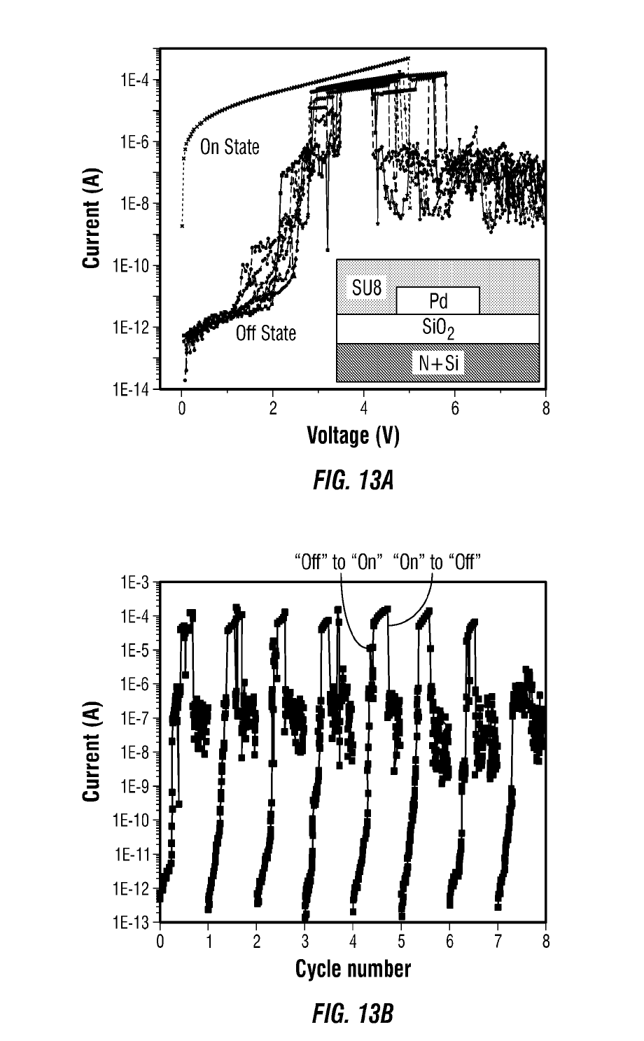

FIGS. 13A-13B show current versus voltage for ON and OFF states (FIG. 13A) and current versus cycle number (FIG. 13B) for a Pd/SiO₂/Si device with SU8 passivation (inset of FIG. 13A) operating in air at room temperature. The SiO₂ memristive device layer was deposited using e-beam evaporation at 130 C, was 51 nm thick, and received no PDA. The Pd upper electrode was fabricated using a liftoff process; therefore, the active oxide layer was exposed to a DI H₂O rinse just prior to Pd evaporation. The inset of FIG. 13A shows the device architecture in cross-section. No sidewall was etched into the SiO₂ layer, thus demonstrating that a sidewall or surface is not needed to achieve reversible switching. As illustrated by the various voltage sweeps in FIG. 13A, the device achieved reversible switching. Furthermore, the device is passivated using a 1 um-thick SU8 epoxy-based photoresist layer hard-baked in air at 120 C for 8 minutes to protect the device from contaminates in the air. The plot in FIG. 13B shows the measured current over time for several voltage sweep cycles switching the device ON and OFF. A total of twenty cycles were applied to this specific device operating in air without failure, whereas, to clearly show each cycle, only eight cycles are shown in FIG. 13B.

It has been observed during initial experimentation that the plasma-assisted treatments described herein performed after top electrode patterning enables device electroformation at much reduced voltage. In some cases, devices are entirely electroformed and no further conditioning is needed to achieve reversible switching. As such, an in situ method to electroform devices in a batch process without the need for direct electrical connection is provided. The devices used in these studies received a PDA in O₂, which was shown above to have little effect on electroformation voltage (see Table 1). Therefore, the significantly reduced voltage needed for electroformation in these devices is attributed to the plasma-assisted RIE of the top electrode. Other devices were treated with a non-etching, Ar plasma after patterning the top electrode, and the results were similar, indicating that the antenna effect can be used to drive a batch, in situ electroformation process.

These methods can be implemented in either the plasma-assisted etch process that forms the upper electrode, or in a subsequent step using a non-etching plasma. Although using a non-etching plasma for the in situ, batch electroformation process will add an additional step to the process flow, the benefits of being able to independently optimize the non-etching process may lead to higher electroformation yield, better reliability, and improved overall device performance.

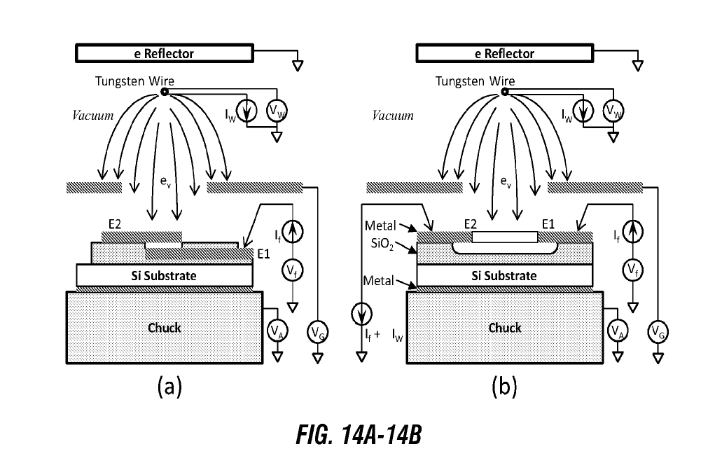

The same antenna effect can be implemented by using a vacuum electron source. FIGS. 14A-14B are schematic representations of a reactor with vacuum electron source using (FIG. 14A) edge ring to contact to lower electrode in vertical device architecture; and (FIG. 14B) modified configuration using two electrical contacts to a planar device architecture. A voltage is applied to a tungsten wire to supply vacuum electrons. The electron reflector is biased to a ground potential so that electrons emitted from the tungsten wire with a velocity component towards the reflector are repelled and directed generally back towards the substrate. A gate electrode biased at V_{G} can be used to control the energy of the vacuum electrons as they imping onto the top electrodes (E2) of the wafer, and also allows only selected regions of the substrate to receive impinging electrons. An edge ring contact can be used to apply voltage V_{f} to lower electrode E1. In this case the electroforming voltage developed across electrodes E2 and E1 will be <0, as opposed to the plasma-assisted case where the developed voltage is >0. Control of chuck bias V_{A}, with V_{A}>V_{f}>V_{G}>0, can be further used to control the antenna effect. It may be noted that an antenna effect voltage will still develop across E2 and E1 even when the bias circuitry supplying V_{f} is not used; however, including V_{f} in the circuit allows more precise control of the antenna voltage that develops across the electrodes. Adding a second electrical connection to the circuit as shown in FIG. 14B allows devices in a planar geometry to be electroformed with the assistance of the vacuum electron source.

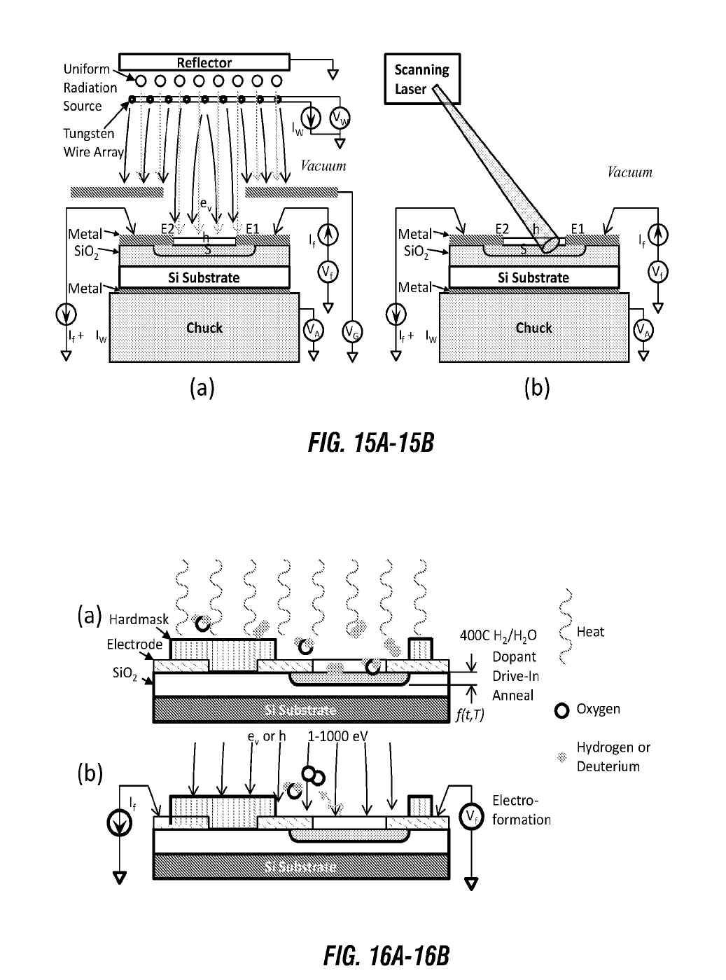

FIGS. 15A-15B show schematic representation of a reactor with: (FIG. 15A) global thermal energy source using a bank of tungsten halogen lamps to aid electroformation of planar device; and (FIG. 15B) a configuration using a scanning laser as the thermal energy source to directly write devices. The use of a global thermal energy source applied to the substrate can be used to further induce device electroformation. In this specific case, the thermal energy source is in the form of a uniform optical and/or infrared radiation source, for example a bank of tungsten halogen lamps, and the thermal source is used in conjunction with a vacuum electron source comprised of a bank of tungsten wires and direct electrical connections to apply an electrical bias during the electroforming process. The optical source could also be used with only the electrical bias connections. Alternatively, as shown in FIG. 15B, selected areas of the substrate can be exposed to a thermal energy source in the form of a scanning laser in order to drive the device electroformation process only in selected areas while leaving other areas of the substrate unexposed. In this way devices can be directly written into a dielectric layer between two electrodes on the substrate.

The surface (S) of the dielectric between the electrodes can be treated with thermal anneal in reducing ambient, as described above, prior to optical energy or vacuum electron exposure in order to lower the threshold for electroformation. Using thermal anneal treatments of less than about 450 C allows metal electrodes to be patterned prior to the treatment and used as a hardmask during the reducing anneal so that only the dielectric surfaces between electrodes are exposed to the reducing ambient.

FIGS. 16A-16B show selective-area device formation using thermal anneal after electrode patterning. FIG. 16A shows reducing anneal process and dopant drive-in to form a region with low electroforming threshold. FIG. 16B shows the subsequent electroformation using direct biasing, vacuum electrons, or thermal energy. Exposure of the surface to reducing anneal in H₂, H₂O, D₂ or D₂O ambient introduces these impurities into the surface. The depth 8 that these dopant impurities travel into the dielectric layer is controlled by anneal temperature T and time t, and the diffusion coefficient of the dopant species. The hardmask layer can be used, if desired, to block exposure of some substrate areas to the anneal. In any case, the patterned electrodes also form a mask so that only selected areas of the dielectric surface are treated by the anneal. During electroformation, oxygen and water are released from the surface as the electroformation process proceeds and the dielectric becomes Si-rich, as shown in FIG. 16B.

FIGS. 17A-17B show schematic representations of a reactor with: vacuum electron source using scanning tunneling microscope (FIG. 17A) and a focused, scanning electron beam (FIG. 17B). Selective area electroformation can be achieved using a scanning tunneling microscope as a vacuum electron source, or a focused, scanned electron beam to directly write devices between two biased electrodes. FIG. 17A shows the use of a scanning tunneling microscope (STM), and, as shown in FIG. 17B, selected areas of the substrate can be exposed to a scanning focused electron beam in order to drive the device electroformation process only in selected areas while leaving other areas of the substrate unexposed. In this way devices can be directly written into a dielectric layer between two electrodes on the substrate.

It is further understood that the ability to perform in situ electroformation using a plasma-assisted process is related to the post-deposition anneal in reducing ambient that is applied to the memristive material, for example, using 4% deuterium in nitrogen at 400 C. Silicon oxide materials with high oxygen vacancy content and high point-defect concentration are expected to form hydrogen (or deuterium) complexes that passivate dangling Si bonds at defects in the amorphous silicon oxide network or at Si/SiOₓ interfaces. The post-deposition anneal will also densify the oxide layer and will remove defects such as “pin-holes” and other structural defects. An upper bound to useful anneal temperatures may be reached if the rate of point-defect removal by thermal anneal exceeds the rate of hydrogen (or deuterium) defect passivation. A lower bound to useful anneal temperatures may be reached when the rate of hydrogen (or deuterium) defect passivation is reduced to less than the rate of point-defect removal by thermal anneal. Since even passivated defects can be removed by thermal anneal, longer anneal times may provide lower point-defect levels, especially when using a high temperature anneal (>450 C). The combination of anneal time and temperature should provide enough thermal energy to remove pin-holes and other structural defects, while also forming hydrogen (or deuterium) complexes with as-deposited point defects. An optimal reducing anneal process is likely to exist where the temperature is tuned so that the rate of defect passivation exceeds the rate of point-defect thermal anneal, and the time is set to achieve a maximum concentration of passivated point defects.

Deuterium is more effective than hydrogen for passivation of Si dangling bond defects. In silicon oxide memristive materials, deuterium may provide a more robust defect passivation so that bulk defect concentration in the thin film remains near the as-deposited defect concentration, even after subsequent processing with exposure to additional thermal treatments. High defect concentrations are expected to promote higher leakage current and therefore should lead to device electroformation at lower voltage.

Finally, it is understood that the effects of post-deposition anneal will depend on the as-deposited defect concentration of the memristive material. For high-quality oxides grown by thermal oxidation of Si, fewer defects will be present as compared to an oxide deposited using, for example, plasma-enhanced chemical vapor deposition, due to differences in film microstructure as a result of deposition process settings and reactant chemistries. Silicon oxide memristive materials with high defect concentrations have higher leakage current and require lower electroforming voltage.

It is concluded that silicon oxide post-deposition anneal in reducing ambient provides a robust defect passivation that helps preserve the as-deposited point-defect concentration, leading to lower electroforming voltage and the ability to form memristive devices in bulk silicon oxide materials. Batch electroformation can be achieved in bulk devices during a plasma-assisted etch of the upper electrode, in a non-etching plasma reactor after upper electrode patterning, or using a vacuum electron source. As a result of being able to form the device within the silicon oxide bulk, standard passivation materials can be used to fully integrate the device with state-of-the-art microelectronics technology platforms.

Memristive devices are also discussed in International Patent Application PCT/US2011/050812 filed Sep. 8, 2011, which claims priority to U.S. Provisional Patent Application 61/380,842 filed Sep. 8, 2010. U.S. patent application Ser. No. 13/356,237 filed Jan. 23, 2012, which claims priority to U.S. Provisional Patent Application 61/437,065 filed Jan. 28, 2011. All of the abovementioned references are incorporated by reference herein.

Implementations described herein are included to demonstrate particular aspects of the present disclosure. It should be appreciated by those of skill in the art that the implementations described herein merely represent exemplary implementation of the disclosure. Those of ordinary skill in the art should, in light of the present disclosure, appreciate that many changes can be made in the specific implementations described and still obtain a like or similar result without departing from the spirit and scope of the present disclosure. From the foregoing description, one of ordinary skill in the art can easily ascertain the essential characteristics of this disclosure, and without departing from the spirit and scope thereof, can make various changes and modifications to adapt the disclosure to various usages and conditions. The implementations described hereinabove are meant to be illustrative only and should not be taken as limiting of the scope of the disclosure.

What is claimed is:

1. A method for fabricating a memristive device comprising:
forming a first electrode, wherein the first electrode is formed from a conductive or semiconductive material;
depositing a memristive layer, wherein the memristive layer comprises at least one memristive material;
hydrating said memristive layer utilizing a reducing ambient, wherein the reducing ambient is H₂, D₂, H₂O, D₂O, NH₃, H or D containing gas mixtures, or a combination thereof; and
forming a second electrode, wherein said first and second electrodes are separated by said memristive layer.

2. The method of claim 1, wherein said hydrating comprises a thermal anneal of said memristive layer in said reducing ambient.

3. The method of claim 1, wherein said hydrating comprises a plasma treatment of said memristive layer in said reducing ambient.

4. The method of claim 1, wherein said hydrating comprises a deionized water rinse and drying in any inert ambient.

5. The method of claim 1, further comprising electroforming said memristive device, wherein electroformation is performed during plasma-assisted etching of said second electrode.

6. The method of claim 1, further comprising electroforming said memristive device by applying a linear voltage sweep, wherein said electroforming is performed utilizing a plasma treatment, vacuum electron treatment, or a thermal treatment.

7. The method of claim 6, wherein said electroformation voltage is equal to or less than 8V.

8. The method of claim 1, further comprising depositing a passivation layer, wherein said passivation layer is an insulating material.

9. The method of claim 8, further comprising etching said passivation layer utilizing plasma RIE or wet etch.

10. The method of claim 1, wherein the memristive material is SiOₓ, where 1≦x≦2.

11. The method of claim 10, wherein the memristive layer has a thickness greater than or equal to 1 nm and less than or equal to 200 nm.

12. The method of claim 2, wherein said thermal annealing is performed at a temperature greater than or equal to 100° C. and less than or equal to 700° C.

13. The method of claim 2, wherein said thermal annealing is performed for a duration greater than or equal to 30 seconds and less than or equal to 30 minutes.

14. The method of claim 13, wherein said reducing ambient is 4% D₂ in N₂, and said thermal annealing is performed at a temperature of 400° C. for 5 minutes.

15. The method of claim 2, wherein said reducing ambient is deuterium, D₂, diluted from 1% to 20% in inert gas.

16. The method of claim 2, wherein said reducing ambient is hydrogen, H₂, diluted from 1% to 20% in inert gas.

17. The method of claim 2, wherein said reducing ambient is water vapor, H₂O, diluted from 1% to 20% in inert gas.

18. The method of claim 2, wherein said reducing ambient is deuterated water vapor, DₓH₂₋ₓO, where 0<x≦2, diluted from 1% to 20% in inert gas.

19. A method for fabricating a memristive device comprising:
forming a first electrode, wherein the first electrode is formed from a conductive or semiconductive material;
depositing a memristive layer, wherein the memristive layer comprises at least one memristive material;
thermal annealing said memristive layer in a reducing ambient, wherein the reducing ambient is H₂, D₂, H₂O, D₂O, NH₃, H or D containing gas mixtures, or a combination thereof; and
forming a second electrode, wherein said first and second electrodes are separated by said memristive layer.

20. The method of claim 19, wherein the memristive material is SiOₓ, where 1≦x≦2.

21. The method of claim 19, wherein the memristive layer has a thickness greater than or equal to 1 nm and less than or equal to 200 nm.

22. The method of claim 20, wherein said thermal annealing is performed at a temperature greater than or equal to 100° C. and less than or equal to 700° C.

23. The method of claim 20, wherein said thermal annealing is performed for a duration greater than or equal to 30 seconds and less than or equal to 30 minutes.

24. The method of claim 20, wherein said reducing ambient is 4% D₂ in N₂, and said thermal annealing is performed at a temperature of 400° C. for 5 minutes.

25. The method of claim 19, wherein said reducing ambient is deuterium, D₂, diluted from 1% to 20% in inert gas.

26. The method of claim 19, wherein said reducing ambient is hydrogen, H₂, diluted from 1% to 20% in inert gas.

27. The method of claim 19, wherein said reducing ambient is water vapor, H₂O, diluted from 1% to 20% in inert gas.

28. The method of claim 20, wherein said reducing ambient is deuterated water vapor, DₓH₂₋ₓO, where 0<x≦2, diluted from 1% to 20% in inert gas.

29. A method for fabricating a memristive device comprising:
forming a first electrode, wherein the first electrode is formed from a conductive or semiconductive material;
depositing a memristive layer, wherein the memristive layer comprises at least one memristive material;
forming a second electrode, wherein said first and second electrodes are separated by said memristive layer; and
electroforming said memristive layer during plasma-assisted etching of said second electrode.

30. The method of claim 29, wherein an electroformation voltage is equal to or less than 15V.

31. The method of claim 29, further comprising depositing a passivation layer, wherein said passivation layer is an insulating material.

32. The method of claim 31, further comprising etching said passivation layer utilizing plasma RIE or wet etch.

33. A memristive device comprising:
a first electrode;
a second electrode;
a memristive layer disposed between said first and second electrodes, wherein said memristive layer is hydrated utilizing a reducing ambient after deposition, and the reducing ambient is H₂, D₂, H₂O, D₂O, NH₃, H or D containing gas mixtures, or a combination thereof; and
a passivation layer covering exposed portions of said memristive layer.

34. The device of claim 33, wherein said hydrating comprises a thermal anneal of said memristive layer in said reducing ambient.

35. The device of claim 33, wherein said hydrating comprises a plasma treatment of said memristive layer in said reducing ambient.

36. The device of claim 33, wherein said hydrating comprises a deionized water rinse and drying in any inert ambient.

37. The device of claim 33, wherein an electroformation voltage of said memristive layer is equal to or less than 15V.

38. The device of claim 33, wherein an electroformation voltage of said memristive layer is equal to or less than 8V.

39. The device of claim 33, wherein the memristive material is SiOₓ, where 1≦x≦2.

40. The device of claim 33, wherein the memristive layer has a thickness greater than or equal to 1 nm and less than or equal to 200 nm.

41. A memristive device comprising:
a first electrode;
a memristive layer disposed between said first and second electrodes;
a second electrode, wherein said second electrode is etched utilizing plasma-assisted etching, and said plasma-assisted etching electroforms said memristive layer; and
a passivation layer covering exposed portions of said memristive layer.

42. The device of claim 41, wherein an electroformation voltage is equal to or less than 15V.

43. The device of claim 41, wherein said passivation layer is an insulating material.

44. The device of claim 41, wherein the memristive material is SiOₓ, where 1≦x≦2.

45. The device of claim 41, wherein the memristive layer has a thickness greater than or equal to 1 nm and less than or equal to 200 nm.
